(19) United States
(12) Patent Application Publication
(10) Pub. No.: US 2023/0289487 A1
(43) Pub. Date: Sep. 14, 2023

(54) SYSTEMS AND METHODS FOR GENERATING AND USING ASSISTIVE DIGITAL MODELS OF BUILDINGS AND BUILDING EQUIPMENT

(71) Applicant: Johnson Controls Tyco IP Holdings LLP, Milwaukee, WI (US)

(72) Inventors: Gary G. Schmidt, JR., Waukesha, WI (US); Isaac J. Krull, Glendale, WI (US); Jacob J. Bavirsha, Valparaiso, IN (US)

(21) Appl. No.: 18/120,162

(22) Filed: Mar. 10, 2023

Related U.S. Application Data
(60) Provisional application No. 63/318,519, filed on Mar. 10, 2022.

(51) Int. Cl. G06F 30/13; G06F 30/27

(52) U.S. Cl. CPC G06F 30/13; G06F 30/27

(57) ABSTRACT

A system for configuring a digital model of a building includes one or more memory devices having instructions stored thereon that, when executed by one or more processors, cause the one or more processors to perform operations. The operations include receiving project information including project specifications and drawings for the building and generating a digital model of the building based on the project information. Generating the digital model includes extracting, from the project information, one or more schedules, schedule notes, floor plans, or identified tags and associating each with a corresponding location in the project information. The operations may also include presenting, on a user interface, a portion of the project information in a base layer and presenting a model layer overlaying the base layer, which includes model objects representing each of the one or more schedules, schedule notes, floor plans, or identified tags in the digital model.

### CROSS-REFERENCE TO RELATED PATENT APPLICATIONS

This application claims the benefit of and priority to U.S. Provisional Application No. 63/318,519, filed on Mar. 10, 2022, the entire disclosure of which is hereby incorporated by reference herein.

### BACKGROUND

The present disclosure relates generally to a web services system, and more particularly to a web services system configured to provide a digital model of a building derived from mechanical, electric, and plumbing blueprints for assisting the presentation and use of blueprints.

Maintaining occupant comfort in a building requires building equipment, such as heating, ventilating, or cooling (HVAC) equipment, to be installed and operated to control environmental conditions in a building. The specific HVAC equipment installed in a building is often selected based on engineering requirements found in the project specifications and drawings for a building (which includes the mechanical, electric, and plumbing (MEP) blueprints). The project specifications and drawings, including the MEP blueprints specify the details for how a building should be built, including the layout and design of its internal systems in sheets of drawings as schedules, floor plans, and details, a format developed prior to the digital age. However, as building systems grow increasingly complex, MEP blueprints must include an immense and ever growing amount of information, and due to the limits of the traditional sheet format, they must present this in ever more condensed and detailed sheets. When presented on a digital display, it is often not possible to both view the entirety of the sheet while at the same time maintain the legibility of the information within it. Relatedly, reviewing these MEP blueprints and quoting HVAC equipment for a building is often a laborious and time consuming process prone to error because of the sheer volume of information presented in MEP blueprints and their condensed format. A quoting party may also be unaware of how large-scale factors (e.g., geographic location, market size, etc.) affect a project. This all often leads to a large investment of time for possibly inaccurate quotes.

There is, therefore, felt a need for a system and/or method to analyze MEP blueprints and extract the equipment specific information and details necessary to select and quote building equipment components that can meet the engineering needs of the project.

### SUMMARY

One implementation of the present disclosure is a system for configuring a digital model of a building including one or more memory devices having instructions stored thereon that, when executed by one or more processors, cause the one or more processors to perform operations. The operations may include receiving project information including project specifications and drawings of the building, and generating a digital model of the building based on the project information. Generating the digital model includes extracting, from the project information, one or more schedules, schedule notes, floor plans, or identified tags and associating each of the one or more schedules, schedule notes, floor plans, or identified tags with a corresponding location in the project information. The operations may further include presenting, on a user interface, a portion of the project information in a base layer and presenting, on the user interface, a model layer overlaying the base layer, the model layer comprising one or more model objects representing each of the one or more schedules, schedule notes, floor plans, or identified tags in the digital model, wherein the model objects are rendered in the model layer at a position on the user interface according to the corresponding location of the one or more schedules, schedule notes, floor plans, or identified tags in the base layer.

Another implementation of the present disclosure is a method for configuring a digital model of a building. The method includes the steps of receiving project information including project specifications and drawings for the building, generating a digital model of the building based on the project information. Generating the digital model comprises, extracting, from the project information, one or more schedules, schedule notes, floor plans, or identified tags; an, associating each of the one or more schedules, schedule notes, floor plans, or identified tags with a corresponding location in the project information. The method further includes presenting, on a user interface, a portion of the project information in a base layer, and presenting, on the user interface, a model layer overlaying the base layer, the model layer comprising one or more model objects representing each of the one or more schedules, schedule notes, floor plans, or identified tags in the digital model, wherein the model objects are rendered at a position on the user interface in the model layer according to the corresponding location of the one or more schedules, schedule notes, floor plans, or identified tags in the base layer.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a drawing of a building equipped with a HVAC system, according to some embodiments.

FIG. 2 is a block diagram of a waterside system which can be used to serve the building of FIG. 1, according to some embodiments.

FIG. 3 is a block diagram of an airside system which can be used to serve the building of FIG. 1, according to some embodiments.

FIG. 4 is a block diagram of a building management system (BMS) which can be used to monitor and control the building of FIG. 1, according to some embodiments.

FIG. 5 is a block diagram of another building management system which can be used to monitor and control the building and HVAC system of FIG. 1, according to some embodiments.

FIG. 6 is a block diagram of a configuration tool, according to some embodiments.

FIG. 7 is a flowchart of a process for generating a digital model, according to some embodiments.

FIG. 8 is a flowchart of a process for generating a quote for a project, according to some embodiments.

FIG. 9 is an example interface presented by the configuration tool of FIG. 5, according to some embodiments.

FIG. 10 is an example interface showing an example project creation page, according to some embodiments.

FIG. 11 is an example interface showing an example configuration page, according to some embodiments.

FIG. 12 is an example interface showing an example schedules page, according to some embodiments.

FIG. 13 is an example interface of FIG. 12, showing an example pane for modifying a project, according to some embodiments.

FIG. 14 is an example interface showing an example extracted schedules page, according to some embodiments.

FIG. 15 is an example interface of FIG. 14, showing an example source file of a project, according to some embodiment.

FIG. 16 is an example interface of FIG. 14, showing the example extracted schedules page, according to some embodiments.

FIG. 17 is an example interface of FIG. 14, showing the example extracted schedules page, according to some embodiments.

FIG. 18 is an example interface showing an example of a floor plane page, according to some embodiments.

FIG. 19 is an example interface showing an example of a detected tags page, according to some embodiments.

FIG. 20 is an example interface of FIG. 19, showing the detected tags page, according to some embodiments.

FIG. 21 is a flowchart of a process for generating a digital model and generating a recommendation, according to some embodiments.

### DETAILED DESCRIPTION

Before turning to the Figures, it should be understood that the disclosure is not limited to the details or methodology set forth in the description or illustrated in the figures. It should also be understood that the terminology is for the purpose of description only and should not be regarded as limiting.

Referring generally to the FIGURES, systems and methods for configuring a building equipment system (e.g., building system) are shown, according to various exemplary embodiments. In some embodiments, a configuration tool (e.g., a project planning tool) may be used by dealers, designers, engineers, and vendors of building equipment systems. A building equipment configuration tool may receive and analyze project information from a project and extract essential building equipment information to generate a digital model of the building based on the project information. The project information may include client information (i.e., client name, location), general project information (i.e., budget, location, project type, etc.), project specifications (i.e., schedules, schedule notes, notes, etc.) and drawings (i.e., floor plans, elevations, etc.) or any other information required for quoting and construction a building. In some embodiments, the project specifications and drawings are part of the MEP blueprints. In some embodiments, the project specifications and drawings are separate files. As used herein, project specifications and drawings is used interchangeably with MEP blueprints. In some embodiments, the building equipment system configuration tool may receive the MEP blueprints from a user and use artificial intelligence to identify individual schedules, schedule notes, floor plans, and details; extract relevant equipment information; detect equipment tags; and correlate the tags, schedules, schedules notes, floor plans and details to generate a digital model of MEP blueprints that is specially adapted for display on a digital screen and therefore easier for a quoting party to review and update. In some embodiments, the building equipment system configuration tool allows a quoting party to modify the digital model of the project including adding, deleting, or relocating tags, updating schedules, associating schedule notes with schedules and/or tags, assigning floors to drawings, etc., to improve the digital model and provide a more accurate quote. In some embodiments, the changes made to the digital model by the quoting party are fed back to the artificial intelligence system and used to further update the system, which can then reprocess the MEP blueprints and generate an updated digital model.

In some embodiments, the digital model is used assist a user working with MEP blueprints. In some embodiments, the MEP blueprints may be displayed digitally in a manner that cannot render the information within the blueprints legibly if the blueprints are presented at a sheet-wide level. The digital model may account for this by presenting to the user model objects overlaid on top of the blueprints representing the schedules, schedule notes, floor plans, or tags that are identified in the blueprints. In some embodiments, automatically generated summary tables are also presented next to the blueprints that provide details of the digital model such as extracted equipment tags, schedules, and schedule notes in a more legible and workable format.

In some embodiments, the digital model is used to identify, choose, and quote building equipment components for the project based on the extracted essential building equipment information in the digital model. The building equipment system configuration tool may use the building equipment information from the digital model to select specific building equipment for the digital model and generate a budget, cost information, and other project metrics. The specific building equipment is a combination of building equipment that meets the engineering need represented in the digital model based. The selection and quote for the digital model can then be used for quoting the actual project.

### Building HVAC Systems and Building Management Systems

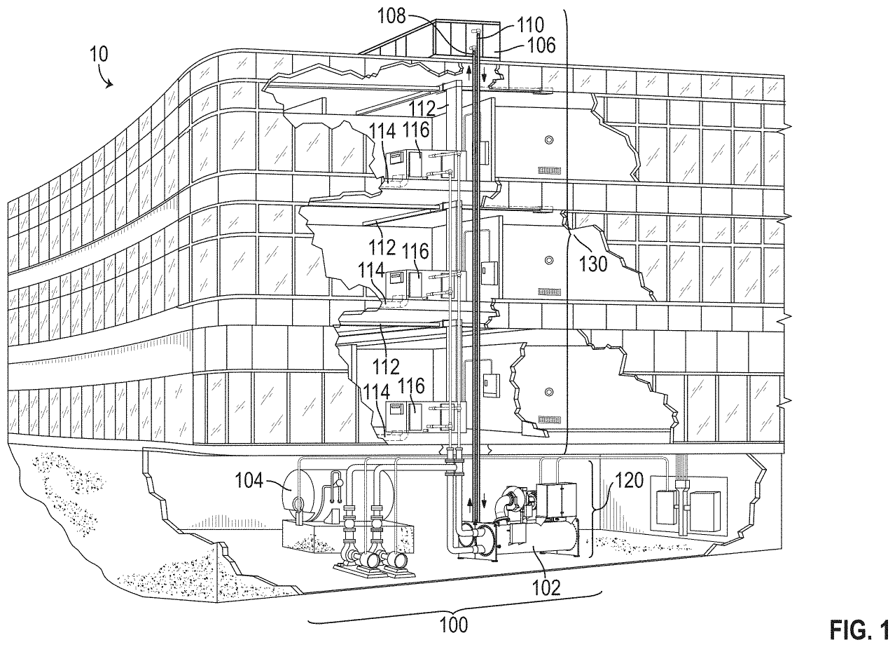

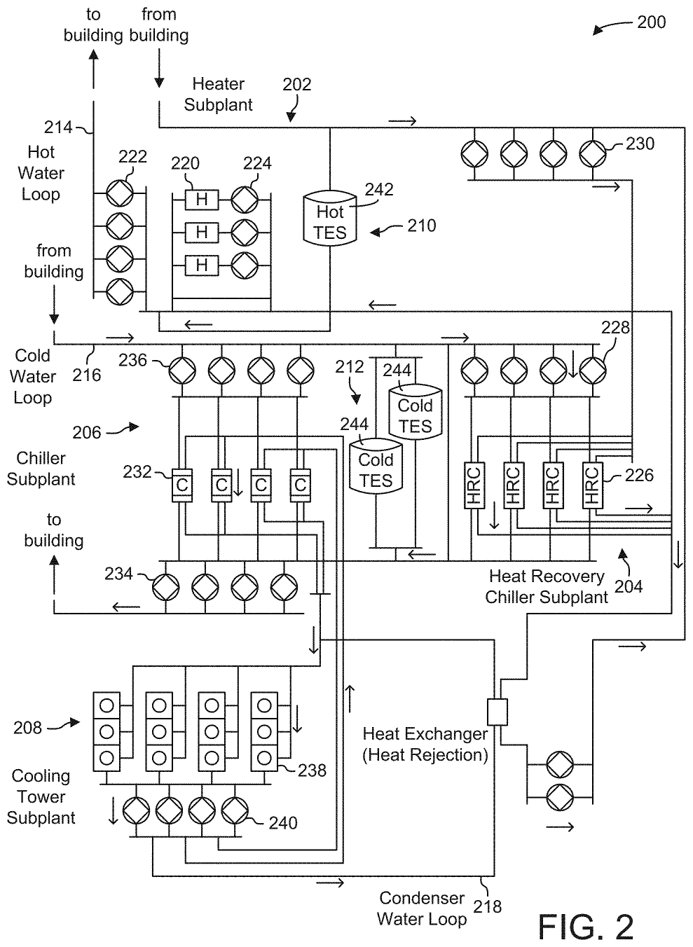

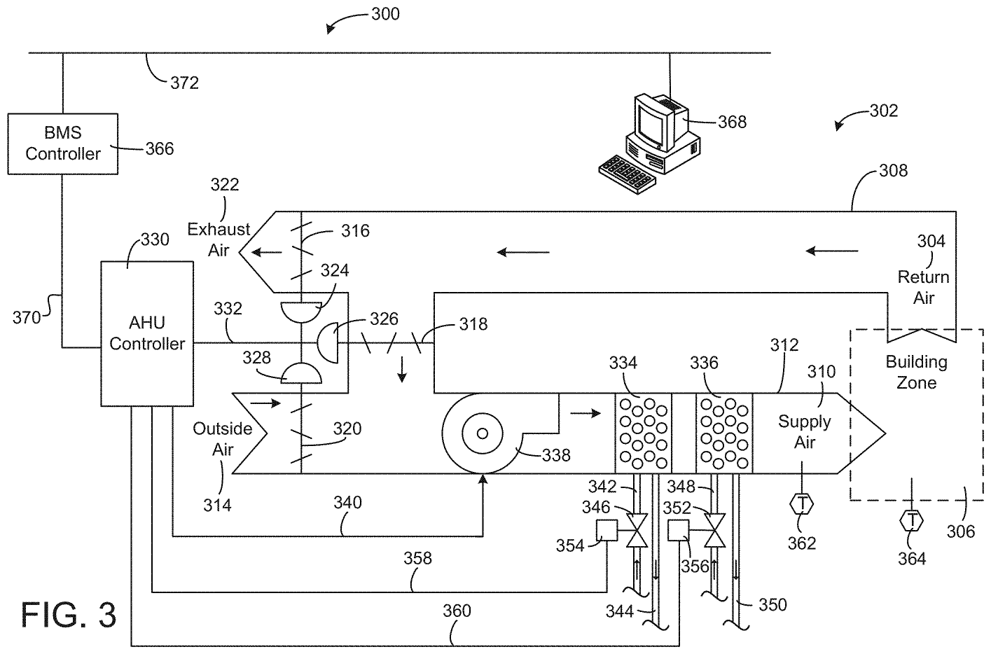

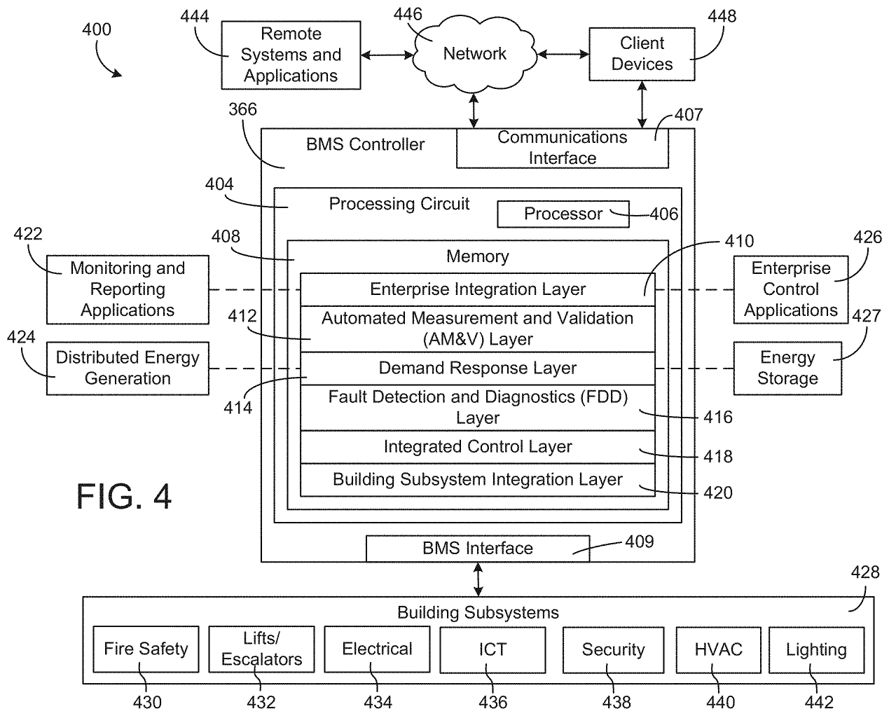

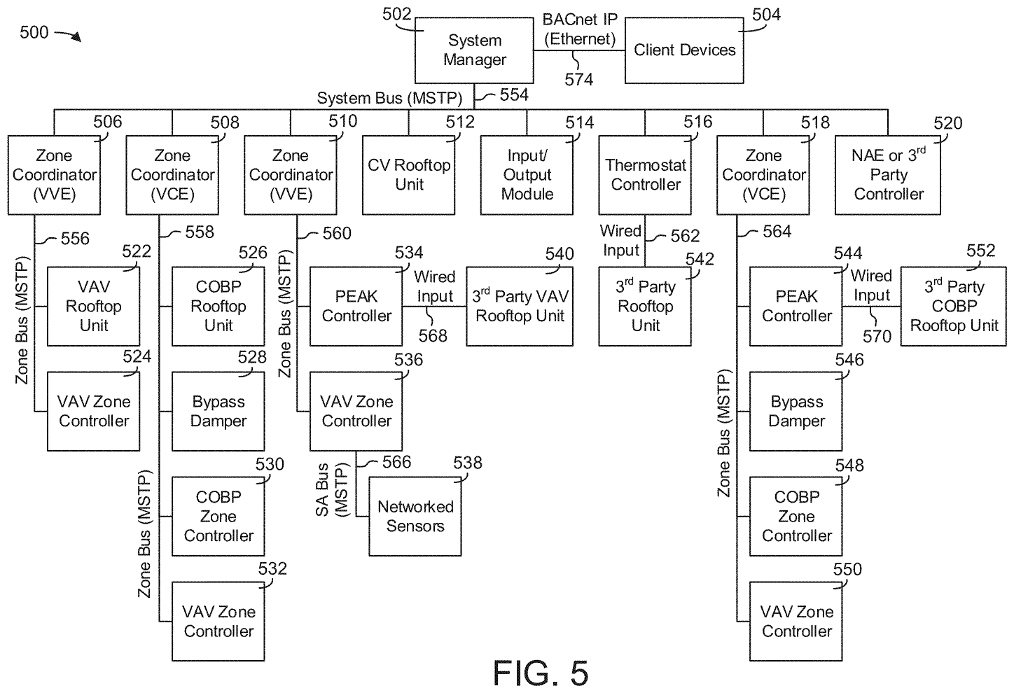

Referring now to FIGS. 1-5, several building management systems (BMS) and HVAC systems in which the systems and methods of the present disclosure can be implemented are shown, according to some embodiments. In brief overview, FIG. 1 shows a building 10 equipped with a HVAC system 100. FIG. 2 is a block diagram of a waterside system 200 which can be used to serve building 10. FIG. 3 is a block diagram of an airside system 300 which can be used to serve building 10. FIG. 4 is a block diagram of a BMS which can be used to monitor and control building 10. FIG. 5 is a block diagram of another BMS which can be used to monitor and control building 10.

### Building and HVAC System

Referring particularly to FIG. 1, a perspective view of a building 10 is shown. Building 10 is served by a BMS. A BMS is, in general, a system of devices configured to control, monitor, and manage equipment in or around a building or building area. A BMS can include, for example, a HVAC system, a security system, a lighting system, a fire alerting system, and any other system that is capable of managing building functions or devices, or any combination thereof.

The BMS that serves building 10 includes a HVAC system 100. HVAC system 100 can include a plurality of HVAC devices (e.g., heaters, chillers, air handling units, pumps, fans, thermal energy storage, etc.) configured to provide heating, cooling, ventilation, or other services for building 10. For example, HVAC system 100 is shown to include a waterside system 120 and an airside system 130. Waterside system 120 may provide a heated or chilled fluid to an air handling unit of airside system 130. Airside system 130 may use the heated or chilled fluid to heat or cool an airflow provided to building 10. An exemplary waterside system and airside system which can be used in HVAC system 100 are described in greater detail with reference to FIGS. 2-3.

HVAC system 100 is shown to include a chiller 102, a boiler 104, and a rooftop air handling unit (AHU) 106. Waterside system 120 may use boiler 104 and chiller 102 to heat or cool a working fluid (e.g., water, glycol, etc.) and may circulate the working fluid to AHU 106. In various embodiments, the HVAC devices of waterside system 120 can be located in or around building 10 (as shown in FIG. 1) or at an offsite location such as a central plant (e.g., a chiller plant, a steam plant, a heat plant, etc.). The working fluid can be heated in boiler 104 or cooled in chiller 102, depending on whether heating or cooling is required in building 10. Boiler 104 may add heat to the circulated fluid, for example, by burning a combustible material (e.g., natural gas) or using an electric heating element. Chiller 102 may place the circulated fluid in a heat exchange relationship with another fluid (e.g., a refrigerant) in a heat exchanger (e.g., an evaporator) to absorb heat from the circulated fluid. The working fluid from chiller 102 and/or boiler 104 can be transported to AHU 106 via piping 108.

AHU 106 may place the working fluid in a heat exchange relationship with an airflow passing through AHU 106 (e.g., via one or more stages of cooling coils and/or heating coils). The airflow can be, for example, outside air, return air from within building 10, or a combination of both. AHU 106 may transfer heat between the airflow and the working fluid to provide heating or cooling for the airflow. For example, AHU 106 can include one or more fans or blowers configured to pass the airflow over or through a heat exchanger containing the working fluid. The working fluid may then return to chiller 102 or boiler 104 via piping 110.

Airside system 130 may deliver the airflow supplied by AHU 106 (i.e., the supply airflow) to building 10 via air supply ducts 112 and may provide return air from building 10 to AHU 106 via air return ducts 114. In some embodiments, airside system 130 includes multiple variable air volume (VAV) units 116. For example, airside system 130 is shown to include a separate VAV unit 116 on each floor or zone of building 10. VAV units 116 can include dampers or other flow control elements that can be operated to control an amount of the supply airflow provided to individual zones of building 10. In other embodiments, airside system 130 delivers the supply airflow into one or more zones of building 10 (e.g., via supply ducts 112) without using intermediate VAV units 116 or other flow control elements. AHU 106 can include various sensors (e.g., temperature sensors, pressure sensors, etc.) configured to measure attributes of the supply airflow. AHU 106 may receive input from sensors located within AHU 106 and/or within the building zone and may adjust the flow rate, temperature, or other attributes of the supply airflow through AHU 106 to achieve setpoint conditions for the building zone.

Waterside System

Referring now to FIG. 2, a block diagram of a waterside system 200 is shown, according to some embodiments. In various embodiments, waterside system 200 may supplement or replace waterside system 120 in HVAC system 100 or can be implemented separate from HVAC system 100. When implemented in HVAC system 100, waterside system 200 can include a subset of the HVAC devices in HVAC system 100 (e.g., boiler 104, chiller 102, pumps, valves, etc.) and may operate to supply a heated or chilled fluid to AHU 106. The HVAC devices of waterside system 200 can be located within building 10 (e.g., as components of waterside system 120) or at an offsite location such as a central plant.

In FIG. 2, waterside system 200 is shown as a central plant having a plurality of subplants 202-212. Subplants 202-212 are shown to include a heater subplant 202, a heat recovery chiller subplant 204, a chiller subplant 206, a cooling tower subplant 208, a hot thermal energy storage (TES) subplant 210, and a cold thermal energy storage (TES) subplant 212. Subplants 202-212 consume resources (e.g., water, natural gas, electricity, etc.) from utilities to serve thermal energy loads (e.g., hot water, cold water, heating, cooling, etc.) of a building or campus. For example, heater subplant 202 can be configured to heat water in a hot water loop 214 that circulates the hot water between heater subplant 202 and building 10. Chiller subplant 206 can be configured to chill water in a cold water loop 216 that circulates the cold water between chiller subplant 206 and building 10. Heat recovery chiller subplant 204 can be configured to transfer heat from cold water loop 216 to hot water loop 214 to provide additional heating for the hot water and additional cooling for the cold water. Condenser water loop 218 may absorb heat from the cold water in chiller subplant 206 and reject the absorbed heat in cooling tower subplant 208 or transfer the absorbed heat to hot water loop 214. Hot TES subplant 210 and cold TES subplant 212 may store hot and cold thermal energy, respectively, for subsequent use.

Hot water loop 214 and cold water loop 216 may deliver the heated and/or chilled water to air handlers located on the rooftop of building 10 (e.g., AHU 106) or to individual floors or zones of building 10 (e.g., VAV units 116). The air handlers push air past heat exchangers (e.g., heating coils or cooling coils) through which the water flows to provide heating or cooling for the air. The heated or cooled air can be delivered to individual zones of building 10 to serve thermal energy loads of building 10. The water then returns to subplants 202-212 to receive further heating or cooling.

Although subplants 202-212 are shown and described as heating and cooling water for circulation to a building, it is understood that any other type of working fluid (e.g., glycol, CO2, etc.) can be used in place of or in addition to water to serve thermal energy loads. In other embodiments, subplants 202-212 may provide heating and/or cooling directly to the building or campus without requiring an intermediate heat transfer fluid. These and other variations to waterside system 200 are within the teachings of the present disclosure.

Each of subplants 202-212 can include a variety of equipment configured to facilitate the functions of the subplant. For example, heater subplant 202 is shown to include a plurality of heating elements 220 (e.g., boilers, electric heaters, etc.) configured to add heat to the hot water in hot water loop 214. Heater subplant 202 is also shown to include several pumps 222 and 224 configured to circulate the hot water in hot water loop 214 and to control the flow rate of the hot water through individual heating elements 220. Chiller subplant 206 is shown to include a plurality of chillers 232 configured to remove heat from the cold water in cold water loop 216. Chiller subplant 206 is also shown to include several pumps 234 and 236 configured to circulate the cold water in cold water loop 216 and to control the flow rate of the cold water through individual chillers 232.

Heat recovery chiller subplant 204 is shown to include a plurality of heat recovery heat exchangers 226 (e.g., refrigeration circuits) configured to transfer heat from cold water loop 216 to hot water loop 214. Heat recovery chiller subplant 204 is also shown to include several pumps 228 and 230 configured to circulate the hot water and/or cold water through heat recovery heat exchangers 226 and to control the flow rate of the water through individual heat recovery heat exchangers 226. Cooling tower subplant 208 is shown to include a plurality of cooling towers 238 configured to remove heat from the condenser water in condenser water loop 218. Cooling tower subplant 208 is also shown to include several pumps 240 configured to circulate the condenser water in condenser water loop 218 and to control the flow rate of the condenser water through individual cooling towers 238.

Hot TES subplant 210 is shown to include a hot TES tank 242 configured to store the hot water for later use. Hot TES subplant 210 may also include one or more pumps or valves configured to control the flow rate of the hot water into or out of hot TES tank 242. Cold TES subplant 212 is shown to include cold TES tanks 244 configured to store the cold water for later use. Cold TES subplant 212 may also include one or more pumps or valves configured to control the flow rate of the cold water into or out of cold TES tanks 244.

In some embodiments, one or more of the pumps in waterside system 200 (e.g., pumps 222, 224, 228, 230, 234, 236, and/or 240) or pipelines in waterside system 200 include an isolation valve associated therewith. Isolation valves can be integrated with the pumps or positioned upstream or downstream of the pumps to control the fluid flows in waterside system 200. In various embodiments, waterside system 200 can include more, fewer, or different types of devices and/or subplants based on the particular configuration of waterside system 200 and the types of loads served by waterside system 200.

### Airside System

Referring now to FIG. 3, a block diagram of an airside system 300 is shown, according to some embodiments. In various embodiments, airside system 300 may supplement or replace airside system 130 in HVAC system 100 or can be implemented separate from HVAC system 100. When implemented in HVAC system 100, airside system 300 can include a subset of the HVAC devices in HVAC system 100 (e.g., AHU 106, VAV units 116, ducts 112-114, fans, dampers, etc.) and can be located in or around building 10. Airside system 300 may operate to heat or cool an airflow provided to building 10 using a heated or chilled fluid provided by waterside system 200.

In FIG. 3, airside system 300 is shown to include an economizer-type air handling unit (AHU) 302. Economizer-type AHUs vary the amount of outside air and return air used by the air handling unit for heating or cooling. For example, AHU 302 may receive return air 304 from building zone 306 via return air duct 308 and may deliver supply air 310 to building zone 306 via supply air duct 312. In some embodiments, AHU 302 is a rooftop unit located on the roof of building 10 (e.g., AHU 106 as shown in FIG. 1) or otherwise positioned to receive both return air 304 and outside air 314. AHU 302 can be configured to operate exhaust air damper 316, mixing damper 318, and outside air damper 320 to control an amount of outside air 314 and return air 304 that combine to form supply air 310. Any return air 304 that does not pass through mixing damper 318 can be exhausted from AHU 302 through exhaust damper 316 as exhaust air 322.

Each of dampers 316-320 can be operated by an actuator. For example, exhaust air damper 316 can be operated by actuator 324, mixing damper 318 can be operated by actuator 326, and outside air damper 320 can be operated by actuator 328. Actuators 324-328 may communicate with an AHU controller 330 via a communications link 332. Actuators 324-328 may receive control signals from AHU controller 330 and may provide feedback signals to AHU controller 330. Feedback signals can include, for example, an indication of a current actuator or damper position, an amount of torque or force exerted by the actuator, diagnostic information (e.g., results of diagnostic tests performed by actuators 324-328), status information, commissioning information, configuration settings, calibration data, and/or other types of information or data that can be collected, stored, or used by actuators 324-328. AHU controller 330 can be an economizer controller configured to use one or more control algorithms (e.g., state-based algorithms, extremum seeking control (ESC) algorithms, proportional-integral (PI) control algorithms, proportional-integral-derivative (PID) control algorithms, model predictive control (MPC) algorithms, feedback control algorithms, etc.) to control actuators 324-328.

Still referring to FIG. 3, AHU 302 is shown to include a cooling coil 334, a heating coil 336, and a fan 338 positioned within supply air duct 312. Fan 338 can be configured to force supply air 310 through cooling coil 334 and/or heating coil 336 and provide supply air 310 to building zone 306. AHU controller 330 may communicate with fan 338 via communications link 340 to control a flow rate of supply air 310. In some embodiments, AHU controller 330 controls an amount of heating or cooling applied to supply air 310 by modulating a speed of fan 338.

Cooling coil 334 may receive a chilled fluid from waterside system 200 (e.g., from cold water loop 216) via piping 342 and may return the chilled fluid to waterside system 200 via piping 344. Valve 346 can be positioned along piping 342 or piping 344 to control a flow rate of the chilled fluid through cooling coil 334. In some embodiments, cooling coil 334 includes multiple stages of cooling coils that can be independently activated and deactivated (e.g., by AHU controller 330, by BMS controller 366, etc.) to modulate an amount of cooling applied to supply air 310.

Heating coil 336 may receive a heated fluid from waterside system 200 (e.g., from hot water loop 214) via piping 348 and may return the heated fluid to waterside system 200 via piping 350. Valve 352 can be positioned along piping 348 or piping 350 to control a flow rate of the heated fluid through heating coil 336. In some embodiments, heating coil 336 includes multiple stages of heating coils that can be independently activated and deactivated (e.g., by AHU controller 330, by BMS controller 366, etc.) to modulate an amount of heating applied to supply air 310.

Each of valves 346 and 352 can be controlled by an actuator. For example, valve 346 can be controlled by actuator 354 and valve 352 can be controlled by actuator 356. Actuators 354-356 may communicate with AHU controller 330 via communications links 358-360. Actuators 354-356 may receive control signals from AHU controller 330 and may provide feedback signals to controller 330. In some embodiments, AHU controller 330 receives a measurement of the supply air temperature from a temperature sensor 362 positioned in supply air duct 312 (e.g., downstream of cooling coil 334 and/or heating coil 336). AHU controller 330 may also receive a measurement of the temperature of building zone 306 from a temperature sensor 364 located in building zone 306.

In some embodiments, AHU controller 330 operates valves 346 and 352 via actuators 354-356 to modulate an amount of heating or cooling provided to supply air 310 (e.g., to achieve a setpoint temperature for supply air 310 or to maintain the temperature of supply air 310 within a setpoint temperature range). The positions of valves 346 and 352 affect the amount of heating or cooling provided to supply air 310 by cooling coil 334 or heating coil 336 and may correlate with the amount of energy consumed to achieve a desired supply air temperature. AHU 330 may control the temperature of supply air 310 and/or building zone 306 by activating or deactivating coils 334-336, adjusting a speed of fan 338, or a combination of both.

Still referring to FIG. 3, airside system 300 is shown to include a building management system (BMS) controller 366 and a client device 368. BMS controller 366 can include one or more computer systems (e.g., servers, supervisory controllers, subsystem controllers, etc.) that serve as system level controllers, application or data servers, head nodes, or master controllers for airside system 300, waterside system 200, HVAC system 100, and/or other controllable systems that serve building 10. BMS controller 366 may communicate with multiple downstream building systems or subsystems (e.g., HVAC system 100, a security system, a lighting system, waterside system 200, etc.) via a communications link 370 according to like or disparate protocols (e.g., LON, BACnet, etc.). In various embodiments, AHU controller 330 and BMS controller 366 can be separate (as shown in FIG. 3) or integrated. In an integrated implementation, AHU controller 330 can be a software module configured for execution by a processor of BMS controller 366.

In some embodiments, AHU controller 330 receives information from BMS controller 366 (e.g., commands, setpoints, operating boundaries, etc.) and provides information to BMS controller 366 (e.g., temperature measurements, valve or actuator positions, operating statuses, diagnostics, etc.). For example, AHU controller 330 may provide BMS controller 366 with temperature measurements from temperature sensors 362-364, equipment on/off states, equipment operating capacities, and/or any other information that can be used by BMS controller 366 to monitor or control a variable state or condition within building zone 306.

Client device 368 can include one or more human-machine interfaces or client interfaces (e.g., graphical user interfaces, reporting interfaces, text-based computer interfaces, client-facing web services, web servers that provide pages to web clients, etc.) for controlling, viewing, or otherwise interacting with HVAC system 100, its subsystems, and/or devices. Client device 368 can be a computer workstation, a client terminal, a remote or local interface, or any other type of user interface device. Client device 368 can be a stationary terminal or a mobile device. For example, client device 368 can be a desktop computer, a computer server with a user interface, a laptop computer, a tablet, a smartphone, a PDA, or any other type of mobile or non-mobile device. Client device 368 may communicate with BMS controller 366 and/or AHU controller 330 via communications link 372.

### Building Management Systems

Referring now to FIG. 4, a block diagram of a building management system (BMS) 400 is shown, according to some embodiments. BMS 400 can be implemented in building 10 to automatically monitor and control various building functions. BMS 400 is shown to include BMS controller 366 and a plurality of building subsystems 428. Building subsystems 428 are shown to include a building electrical subsystem 434, an information communication technology (ICT) subsystem 436, a security subsystem 438, a HVAC subsystem 440, a lighting subsystem 442, a lift/escalators subsystem 432, and a fire safety subsystem 430. In various embodiments, building subsystems 428 can include fewer, additional, or alternative subsystems. For example, building subsystems 428 may also or alternatively include a refrigeration subsystem, an advertising or signage subsystem, a cooking subsystem, a vending subsystem, a printer or copy service subsystem, or any other type of building subsystem that uses controllable equipment and/or sensors to monitor or control building 10. In some embodiments, building subsystems 428 include waterside system 200 and/or airside system 300, as described with reference to FIGS. 2-3.

Each of building subsystems 428 can include any number of devices, controllers, and connections for completing its individual functions and control activities. HVAC subsystem 440 can include many of the same components as HVAC system 100, as described with reference to FIGS. 1-3. For example, HVAC subsystem 440 can include a chiller, a boiler, any number of air handling units, economizers, field controllers, supervisory controllers, actuators, temperature sensors, and other devices for controlling the temperature, humidity, airflow, or other variable conditions within building 10. Lighting subsystem 442 can include any number of light fixtures, ballasts, lighting sensors, dimmers, or other devices configured to controllably adjust the amount of light provided to a building space. Security subsystem 438 can include occupancy sensors, video surveillance cameras, digital video recorders, video processing servers, intrusion detection devices, access control devices and servers, or other security-related devices.

Still referring to FIG. 4, BMS controller 366 is shown to include a communications interface 407 and a BMS interface 409. Interface 407 may facilitate communications between BMS controller 366 and external applications (e.g., monitoring and reporting applications 422, enterprise control applications 426, remote systems and applications 444, applications residing on client devices 448, etc.) for allowing user control, monitoring, and adjustment to BMS controller 366 and/or subsystems 428. Interface 407 may also facilitate communications between BMS controller 366 and client devices 448. BMS interface 409 may facilitate communications between BMS controller 366 and building subsystems 428 (e.g., HVAC, lighting security, lifts, power distribution, business, etc.).

Interfaces 407, 409 can be or include wired or wireless communications interfaces (e.g., jacks, antennas, transmitters, receivers, transceivers, wire terminals, etc.) for conducting data communications with building subsystems 428 or other external systems or devices. In various embodiments, communications via interfaces 407, 409 can be direct (e.g., local wired or wireless communications) or via a communications network 446 (e.g., a WAN, the Internet, a cellular network, etc.). For example, interfaces 407, 409 can include an Ethernet card and port for sending and receiving data via an Ethernet-based communications link or network. In another example, interfaces 407, 409 can include a Wi-Fi transceiver for communicating via a wireless communications network. In another example, one or both of interfaces 407, 409 can include cellular or mobile phone communications transceivers. In one embodiment, communications interface 407 is a power line communications interface and BMS interface 409 is an Ethernet interface. In other embodiments, both communications interface 407 and BMS interface 409 are Ethernet interfaces or are the same Ethernet interface.

Still referring to FIG. 4, BMS controller 366 is shown to include a processing circuit 404 including a processor 406 and memory 408. Processing circuit 404 can be communicably connected to BMS interface 409 and/or communications interface 407 such that processing circuit 404 and the various components thereof can send and receive data via interfaces 407, 409. Processor 406 can be implemented as a general purpose processor, an application specific integrated circuit (ASIC), one or more field programmable gate arrays (FPGAs), a group of processing components, or other suitable electronic processing components.

Memory 408 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 408 can be or include volatile memory or non-volatile memory. Memory 408 can include database components, object code components, script components, or any other type of information structure for supporting the various activities and information structures described in the present application. According to some embodiments, memory 408 is communicably connected to processor 406 via processing circuit 404 and includes computer code for executing (e.g., by processing circuit 404 and/or processor 406) one or more processes described herein.

In some embodiments, BMS controller 366 is implemented within a single computer (e.g., one server, one housing, etc.). In various other embodiments BMS controller 366 can be distributed across multiple servers or computers (e.g., that can exist in distributed locations). Further, while FIG. 4 shows applications 422 and 426 as existing outside of BMS controller 366, in some embodiments, applications 422 and 426 can be hosted within BMS controller 366 (e.g., within memory 408).

Still referring to FIG. 4, memory 408 is shown to include an enterprise integration layer 410, an automated measurement and validation (AM&V) layer 412, a demand response (DR) layer 414, a fault detection and diagnostics (FDD) layer 416, an integrated control layer 418, and a building subsystem integration later 420. Layers 410-420 can be configured to receive inputs from building subsystems 428 and other data sources, determine optimal control actions for building subsystems 428 based on the inputs, generate control signals based on the optimal control actions, and provide the generated control signals to building subsystems 428. The following paragraphs describe some of the general functions performed by each of layers 410-420 in BMS 400.

Enterprise integration layer 410 can be configured to serve clients or local applications with information and services to support a variety of enterprise-level applications. For example, enterprise control applications 426 can be configured to provide subsystem-spanning control to a graphical user interface (GUI) or to any number of enterprise-level business applications (e.g., accounting systems, user identification systems, etc.). Enterprise control applications 426 may also or alternatively be configured to provide configuration GUIs for configuring BMS controller 366. In yet other embodiments, enterprise control applications 426 can work with layers 410-420 to optimize building performance (e.g., efficiency, energy use, comfort, or safety) based on inputs received at interface 407 and/or BMS interface 409.

Building subsystem integration layer 420 can be configured to manage communications between BMS controller 366 and building subsystems 428. For example, building subsystem integration layer 420 may receive sensor data and input signals from building subsystems 428 and provide output data and control signals to building subsystems 428. Building subsystem integration layer 420 may also be configured to manage communications between building subsystems 428. Building subsystem integration layer 420 translates communications (e.g., sensor data, input signals, output signals, etc.) across a plurality of multi-vendor/multi-protocol systems.

Demand response layer 414 can be configured to optimize resource usage (e.g., electricity use, natural gas use, water use, etc.) and/or the monetary cost of such resource usage in response to satisfy the demand of building 10. The optimization can be based on time-of-use prices, curtailment signals, energy availability, or other data received from utility providers, distributed energy generation systems 424, from energy storage 427 (e.g., hot TES 242, cold TES 244, etc.), or from other sources. Demand response layer 414 may receive inputs from other layers of BMS controller 366 (e.g., building subsystem integration layer 420, integrated control layer 418, etc.). The inputs received from other layers can include environmental or sensor inputs such as temperature, carbon dioxide levels, relative humidity levels, air quality sensor outputs, occupancy sensor outputs, room schedules, and the like. The inputs may also include inputs such as electrical use (e.g., expressed in kWh), thermal load measurements, pricing information, projected pricing, smoothed pricing, curtailment signals from utilities, and the like.

According to some embodiments, demand response layer 414 includes control logic for responding to the data and signals it receives. These responses can include communicating with the control algorithms in integrated control layer 418, changing control strategies, changing setpoints, or activating/deactivating building equipment or subsystems in a controlled manner. Demand response layer 414 may also include control logic configured to determine when to utilize stored energy. For example, demand response layer 414 may determine to begin using energy from energy storage 427 just prior to the beginning of a peak use hour.

In some embodiments, demand response layer 414 includes a control module configured to actively initiate control actions (e.g., automatically changing setpoints) which minimize energy costs based on one or more inputs representative of or based on demand (e.g., price, a curtailment signal, a demand level, etc.). In some embodiments, demand response layer 414 uses equipment models to determine an optimal set of control actions. The equipment models can include, for example, thermodynamic models describing the inputs, outputs, and/or functions performed by various sets of building equipment. Equipment models may represent collections of building equipment (e.g., subplants, chiller arrays, etc.) or individual devices (e.g., individual chillers, heaters, pumps, etc.).

Demand response layer 414 may further include or draw upon one or more demand response policy definitions (e.g., databases, XML, files, etc.). The policy definitions can be edited or adjusted by a user (e.g., via a graphical user interface) so that the control actions initiated in response to demand inputs can be tailored for the user's application, desired comfort level, particular building equipment, or based on other concerns. For example, the demand response policy definitions can specify which equipment can be turned on or off in response to particular demand inputs, how long a system or piece of equipment should be turned off, what setpoints can be changed, what the allowable set point adjustment range is, how long to hold a high demand setpoint before returning to a normally scheduled setpoint, how close to approach capacity limits, which equipment modes to utilize, the energy transfer rates (e.g., the maximum rate, an alarm rate, other rate boundary information, etc.) into and out of energy storage devices (e.g., thermal storage tanks, battery banks, etc.), and when to dispatch on-site generation of energy (e.g., via fuel cells, a motor generator set, etc.).

Integrated control layer 418 can be configured to use the data input or output of building subsystem integration layer 420 and/or demand response later 414 to make control decisions. Due to the subsystem integration provided by building subsystem integration layer 420, integrated control layer 418 can integrate control activities of the subsystems 428 such that the subsystems 428 behave as a single integrated supersystem. In some embodiments, integrated control layer 418 includes control logic that uses inputs and outputs from a plurality of building subsystems to provide greater comfort and energy savings relative to the comfort and energy savings that separate subsystems could provide alone. For example, integrated control layer 418 can be configured to use an input from a first subsystem to make an energy-saving control decision for a second subsystem. Results of these decisions can be communicated back to building subsystem integration layer 420.

Integrated control layer 418 is shown to be logically below demand response layer 414. Integrated control layer 418 can be configured to enhance the effectiveness of demand response layer 414 by enabling building subsystems 428 and their respective control loops to be controlled in coordination with demand response layer 414. This configuration may advantageously reduce disruptive demand response behavior relative to conventional systems. For example, integrated control layer 418 can be configured to assure that a demand response-driven upward adjustment to the setpoint for chilled water temperature (or another component that directly or indirectly affects temperature) does not result in an increase in fan energy (or other energy used to cool a space) that would result in greater total building energy use than was saved at the chiller.

Integrated control layer 418 can be configured to provide feedback to demand response layer 414 so that demand response layer 414 checks that constraints (e.g., temperature, lighting levels, etc.) are properly maintained even while demanded load shedding is in progress. The constraints may also include setpoint or sensed boundaries relating to safety, equipment operating limits and performance, comfort, fire codes, electrical codes, energy codes, and the like. Integrated control layer 418 is also logically below fault detection and diagnostics layer 416 and automated measurement and validation layer 412. Integrated control layer 418 can be configured to provide calculated inputs (e.g., aggregations) to these higher levels based on outputs from more than one building subsystem.

Automated measurement and validation (AM&V) layer 412 can be configured to verify whether control strategies commanded by integrated control layer 418 or demand response layer 414 are working properly (e.g., using data aggregated by AM&V layer 412, integrated control layer 418, building subsystem integration layer 420, FDD layer 416, or otherwise). The calculations made by AM&V layer 412 can be based on building system energy models and/or equipment models for individual BMS devices or subsystems. For example, AM&V layer 412 may compare a model-predicted output with an actual output from building subsystems 428 to determine an accuracy of the model.

Fault detection and diagnostics (FDD) layer 416 can be configured to provide on-going fault detection for building subsystems 428, building subsystem devices (i.e., building equipment), and control algorithms used by demand response layer 414 and integrated control layer 418. FDD layer 416 may receive data inputs from integrated control layer 418, directly from one or more building subsystems or devices, or from another data source. FDD layer 416 may automatically diagnose and respond to detected faults. The responses to detected or diagnosed faults can include providing an alert message to a user, a maintenance scheduling system, or a control algorithm configured to attempt to repair the fault or to work-around the fault.

FDD layer 416 can be configured to output a specific identification of the faulty component or cause of the fault (e.g., loose damper linkage) using detailed subsystem inputs available at building subsystem integration layer 420. In other exemplary embodiments, FDD layer 416 is configured to provide “fault” events to integrated control layer 418 which executes control strategies and policies in response to the received fault events. According to some embodiments, FDD layer 416 (or a policy executed by an integrated control engine or business rules engine) may shut-down systems or direct control activities around faulty devices or systems to reduce energy waste, extend equipment life, or assure proper control response.

FDD layer 416 can be configured to store or access a variety of different system data stores (or data points for live data). FDD layer 416 may use some content of the data stores to identify faults at the equipment level (e.g., specific chiller, specific AHU, specific terminal unit, etc.) and other content to identify faults at component or subsystem levels. For example, building subsystems 428 may generate temporal (i.e., time-series) data indicating the performance of BMS 400 and the various components thereof. The data generated by building subsystems 428 can include measured or calculated values that exhibit statistical characteristics and provide information about how the corresponding system or process (e.g., a temperature control process, a flow control process, etc.) is performing in terms of error from its setpoint. These processes can be examined by FDD layer 416 to expose when the system begins to degrade in performance and alert a user to repair the fault before it becomes more severe.

Referring now to FIG. 5, a block diagram of another building management system (BMS) 500 is shown, according to some embodiments. BMS 500 can be used to monitor and control the devices of HVAC system 100, waterside system 200, airside system 300, building subsystems 428, as well as other types of BMS devices (e.g., lighting equipment, security equipment, etc.) and/or HVAC equipment.

BMS 500 provides a system architecture that facilitates automatic equipment discovery and equipment model distribution. Equipment discovery can occur on multiple levels of BMS 500 across multiple different communications busses (e.g., a system bus 554, zone buses 556-560 and 564, sensor/actuator bus 566, etc.) and across multiple different communications protocols. In some embodiments, equipment discovery is accomplished using active node tables, which provide status information for devices connected to each communications bus. For example, each communications bus can be monitored for new devices by monitoring the corresponding active node table for new nodes. When a new device is detected, BMS 500 can begin interacting with the new device (e.g., sending control signals, using data from the device) without user interaction.

Some devices in BMS 500 present themselves to the network using equipment models. An equipment model defines equipment object attributes, view definitions, schedules, trends, and the associated BACnet value objects (e.g., analog value, binary value, multistate value, etc.) that are used for integration with other systems. Some devices in BMS 500 store their own equipment models. Other devices in BMS 500 have equipment models stored externally (e.g., within other devices). For example, a zone coordinator 508 can store the equipment model for a bypass damper 528. In some embodiments, zone coordinator 508 automatically creates the equipment model for bypass damper 528 or other devices on zone bus 558. Other zone coordinators can also create equipment models for devices connected to their zone busses. The equipment model for a device can be created automatically based on the types of data points exposed by the device on the zone bus, device type, and/or other device attributes. Several examples of automatic equipment discovery and equipment model distribution are discussed in greater detail below.

Still referring to FIG. 5, BMS 500 is shown to include a system manager 502; several zone coordinators 506, 508, 510 and 518; and several zone controllers 524, 530, 532, 536, 548, and 550. System manager 502 can monitor data points in BMS 500 and report monitored variables to various monitoring and/or control applications. System manager 502 can communicate with client devices 504 (e.g., user devices, desktop computers, laptop computers, mobile devices, etc.) via a data communications link 574 (e.g., BACnet IP, Ethernet, wired or wireless communications, etc.). System manager 502 can provide a user interface to client devices 504 via data communications link 574. The user interface may allow users to monitor and/or control BMS 500 via client devices 504.

In some embodiments, system manager 502 is connected with zone coordinators 506-510 and 518 via a system bus 554. System manager 502 can be configured to communicate with zone coordinators 506-510 and 518 via system bus 554 using a master-slave token passing (MSTP) protocol or any other communications protocol. System bus 554 can also connect system manager 502 with other devices such as a constant volume (CV) rooftop unit (RTU) 512, an input/output module (TOM) 514, a thermostat controller 516 (e.g., a TEC5000 series thermostat controller), and a network automation engine (NAE) or third-party controller 520. RTU 512 can be configured to communicate directly with system manager 502 and can be connected directly to system bus 554. Other RTUs can communicate with system manager 502 via an intermediate device. For example, a wired input 562 can connect a third-party RTU 542 to thermostat controller 516, which connects to system bus 554.

System manager 502 can provide a user interface for any device containing an equipment model. Devices such as zone coordinators 506-510 and 518 and thermostat controller 516 can provide their equipment models to system manager 502 via system bus 554. In some embodiments, system manager 502 automatically creates equipment models for connected devices that do not contain an equipment model (e.g., TOM 514, third party controller 520, etc.). For example, system manager 502 can create an equipment model for any device that responds to a device tree request. The equipment models created by system manager 502 can be stored within system manager 502. System manager 502 can then provide a user interface for devices that do not contain their own equipment models using the equipment models created by system manager 502. In some embodiments, system manager 502 stores a view definition for each type of equipment connected via system bus 554 and uses the stored view definition to generate a user interface for the equipment.

Each zone coordinator 506-510 and 518 can be connected with one or more of zone controllers 524, 530-532, 536, and 548-550 via zone buses 556, 558, 560, and 564. Zone coordinators 506-510 and 518 can communicate with zone controllers 524, 530-532, 536, and 548-550 via zone busses 556-560 and 564 using a MSTP protocol or any other communications protocol. Zone busses 556-560 and 564 can also connect zone coordinators 506-510 and 518 with other types of devices such as variable air volume (VAV) RTUs 522 and 540, changeover bypass (COBP) RTUs 526 and 552, bypass dampers 528 and 546, and PEAK controllers 534 and 544.

Zone coordinators 506-510 and 518 can be configured to monitor and command various zoning systems. In some embodiments, each zone coordinator 506-510 and 518 monitors and commands a separate zoning system and is connected to the zoning system via a separate zone bus. For example, zone coordinator 506 can be connected to VAV RTU 522 and zone controller 524 via zone bus 556. Zone coordinator 508 can be connected to COBP RTU 526, bypass damper 528, COBP zone controller 530, and VAV zone controller 532 via zone bus 558. Zone coordinator 510 can be connected to PEAK controller 534 and VAV zone controller 536 via zone bus 560. Zone coordinator 518 can be connected to PEAK controller 544, bypass damper 546, COBP zone controller 548, and VAV zone controller 550 via zone bus 564.

A single model of zone coordinator 506-510 and 518 can be configured to handle multiple different types of zoning systems (e.g., a VAV zoning system, a COBP zoning system, etc.). Each zoning system can include a RTU, one or more zone controllers, and/or a bypass damper. For example, zone coordinators 506 and 510 are shown as Verasys VAV engines (VVEs) connected to VAV RTUs 522 and 540, respectively. Zone coordinator 506 is connected directly to VAV RTU 522 via zone bus 556, whereas zone coordinator 510 is connected to a third-party VAV RTU 540 via a wired input 568 provided to PEAK controller 534. Zone coordinators 508 and 518 are shown as Verasys COBP engines (VCEs) connected to COBP RTUs 526 and 552, respectively. Zone coordinator 508 is connected directly to COBP RTU 526 via zone bus 558, whereas zone coordinator 518 is connected to a third-party COBP RTU 552 via a wired input 570 provided to PEAK controller 544.

Zone controllers 524, 530-532, 536, and 548-550 can communicate with individual BMS devices (e.g., sensors, actuators, etc.) via sensor/actuator (SA) busses. For example, VAV zone controller 536 is shown connected to networked sensors 538 via SA bus 566. Zone controller 536 can communicate with networked sensors 538 using a MSTP protocol or any other communications protocol. Although only one SA bus 566 is shown in FIG. 5, it should be understood that each zone controller 524, 530-532, 536, and 548-550 can be connected to a different SA bus. Each SA bus can connect a zone controller with various sensors (e.g., temperature sensors, humidity sensors, pressure sensors, light sensors, occupancy sensors, etc.), actuators (e.g., damper actuators, valve actuators, etc.) and/or other types of controllable equipment (e.g., chillers, heaters, fans, pumps, etc.).

Each zone controller 524, 530-532, 536, and 548-550 can be configured to monitor and control a different building zone. Zone controllers 524, 530-532, 536, and 548-550 can use the inputs and outputs provided via their SA busses to monitor and control various building zones. For example, a zone controller 536 can use a temperature input received from networked sensors 538 via SA bus 566 (e.g., a measured temperature of a building zone) as feedback in a temperature control algorithm. Zone controllers 524, 530-532, 536, and 548-550 can use various types of control algorithms (e.g., state-based algorithms, extremum seeking control (ESC) algorithms, proportional-integral (PI) control algorithms, proportional-integral-derivative (PID) control algorithms, model predictive control (MPC) algorithms, feedback control algorithms, etc.) to control a variable state or condition (e.g., temperature, humidity, airflow, lighting, etc.) in or around building 10.

### Assistive Digital Model

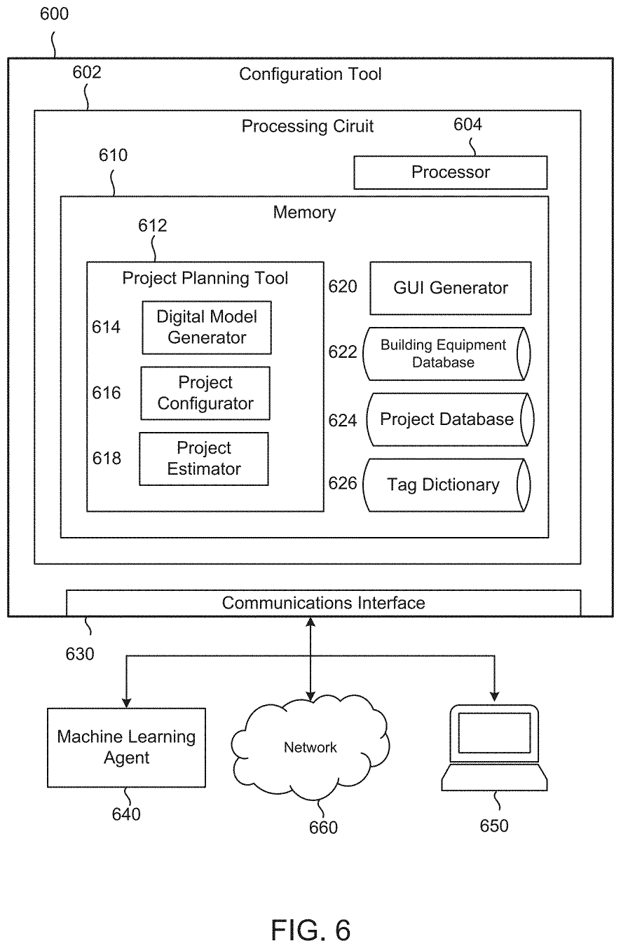

Referring now to FIG. 6, a block diagram of a configuration tool 600 is shown, according to an exemplary embodiment. Configuration tool 600 is generally configured to allow a user to generate a digital model of a building based on project information, select building equipment components using a machine learning agent that meet the engineering requirements of the building as represented in the digital model, and provide the selected building equipment to a configure, price, quote (CPQ) tool. Specifically, configuration tool 600 may be configured to receive project information including mechanical, electric, and plumbing (MEP) blueprints (i.e., project specifications and drawings) of a building and generate a digital model of the building from the MEP blueprints using a machine learning agent. In some embodiments, the configuration tool 600 may be configured to present the digital model to a user in a model layer over top of a base layer including the blueprints, where the model layer comprises one or more model objects representing the information from the blueprints which is included in the digital model. In some embodiments, the configuration tool 600 is configured to provide the digital model to the machine learning agent for selecting one or more building equipment components for use in the building based on the information in the digital model. In some embodiments, the selected building equipment components are then used to generate a quote for the cost of the components that can be delivered to a requesting party.

Configuration tool 600 is shown to include a processing circuit 602 that further includes processor 604 and a memory 610. While shown as single components, it will be appreciated that processor 604 and/or memory 610 may include multiple components (e.g., multiple processors or multiple memory devices). In some embodiments, memory 610 may be a local or remote memory. Likewise, in some embodiments, configuration tool 600 itself is implemented within a single computer (e.g., one server, one housing, etc.) or can be distributed across multiple servers or computers (e.g. that can exist in distributed locations). In some such embodiments, the distributed serves or computers are communicably coupled via network 660, described in greater detail below. All such implementations are contemplated herein.

Processor 604 can be implemented as a general purpose processor, an application specific integrated circuit (ASIC), or more field programmable gate arrays (FPGAs), a group of processing components, or other suitable electronic processing components. Memory 610 (e.g., memory, memory unit, storage device, etc.) can include one or more devices (e.g., RAM, ROM, Flash memory, hard disk storage, etc.) for storing data and/or computer code for completing or facilitating the various processes, layers and modules described in the present application. Memory 610 can be or include volatile memory or non-volatile memory. Memory 610 can include database components, object code components, script components, or any other type of information structure for supporting the various activities and information structures described in the present application. According to an example embodiment, memory 610 is communicably connected to processor 604 via processing circuit 602 and includes computer code for executing (e.g., by processing circuit 602 and/or processor 604) one or more processes described herein.

Memory 610 is shown to include project planning tool 612 configured to generate a digital model of a project from project information and use the digital model to select and price building equipment components for the project. More specifically, the project planning tool 612 is configured to receive project information such as project specifications and drawings (i.e., MEP blueprints), client information, and any other information relevant to the project, and extract details necessary to build the digital model of the project including schedules, schedule notes, floor plans, and equipment tags. In some embodiments, the project planning tool 612 may be configured to use the digital model to select building equipment components for the project and provided a cost estimate or quote based on the selected components.

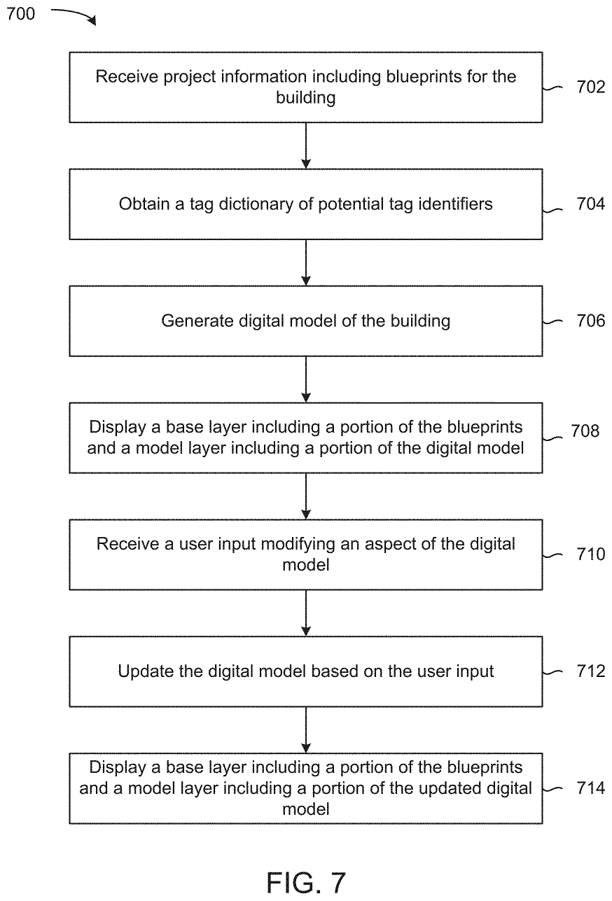

In some embodiments, the project planning tool 612 is configured to manage information input by a user, and also manage information stored within memory 610 to generate the digital model and select building equipment components to determine an estimated quote for the project. In some embodiments, the project planning tool 612 is configured to interact with a machine learning agent 640 to build the digital model and select the building equipment components. In some embodiments, the project planning tool 612 is configured to accept user inputs modifying the digital model including modifying a schedule, floor plan, or equipment tag. As shown in FIG. 6, project planning tool 612 includes digital model generator 614, project configurator 616, and project estimator 618. Various aspects and/or functions of these components are described in detail with reference to FIGS. 7-21.

In some embodiments, digital model generator 614 is configured to receive project information and generate a digital model of the project. The project information may include details for constructing a digital model and information for determining the engineering requirements for each building equipment type included in the project information. Project information may include, for example, a project name, a primary contractor, and/or project specifications and drawings (i.e., the MEP blueprints for the project), amongst other information. MEP blueprints may be a set of engineering drawing sheets for the project with schedules, schedule notes, floor plans, and details indicating the position and technical requirements for one or more pieces of building equipment. Each sheet of the project information may include one or more schedules, schedule notes, floor plans, or detail views of the building, and together, the sheets may represent the physical layout of the entire project. The digital model generator 614 may be configured to analyze the sheets and generate a digital model of the building by aggregating information from each of the sheets into the single digital model. The extracted information may include one or more schedules, one or more schedule notes, one or more floor plans, or one or more tags, or any combination thereof. For example, project information may not include schedule notes. The extracted aggregated information in the digital model may be associated with the location of the aggregated information in the original project information. The digital model may therefore represent the entire building. Schedules are generally formatted as tables and include specific information regarding features shown in the drawings. In some embodiments, schedules include quantities, tag names, sizes, descriptions, performance characteristics, and other details for building equipment shown in the floor plans and details. Schedule notes similarly contain supplemental information on project requirements or specifications that may be necessary for choosing the proper building equipment. The drawings are graphical representations of a portion of the building. In some embodiments, the drawings (i.e., the floor plans and details) include a layout for a particular section of the project as well as the indications of the location of various pieces of building equipment. The location of various pieces of building equipment may be indicated with an equipment tag. In some embodiments, the equipment tags in the floor plan may correlate with one or more tags found in a schedule or schedule notes. A tag may be an alphanumeric text string such as a label and/or a symbol.

In some embodiments, the digital model generator 614 receives a tag dictionary to be used when building the digital model, shown as tag dictionary 626. Tag dictionary 626 may include a list of potential tag identifiers for digital model generator 614 to use in order to find equipment tags and other desired data in the project information. Potential tag identifiers may be letters or words that precede and/or indicate an equipment tag/desired information will follow (e.g., “mark no.”, “RTU code,” “fan no.,” “sheet no.,” etc.). In some embodiments, the tag dictionary is populated with potential tag identifiers based on prior projects, such as information found in project database 624. For example, machine learning agent 640 may receive information regarding past projects from project database 624, and based on the identified tags and tag identifiers in the past projects, generate a list of potential tag identifiers to be searched for in the current process. In some embodiments, the digital model generator 614 allows a user to edit the tag dictionary 626, including adding, removing, and modifying one or more tag identifiers in the list.

In some embodiments, digital model generator 614 identifies and extracts the schedules, schedule notes, floor plans, and equipment tags from the project information, for example the MEP blueprints. In some embodiments, the digital model generator 614 uses the tag dictionary 626 as a reference for identifying and locating the equipment tags and other desired information in the project information based on the list of potential tag identifiers. In some embodiments, the tag dictionary 626 contains multiple lists of potential tag identifiers that may be used. There may be multiple instances of the same equipment tag throughout the project, and each instance of the equipment tag can be identified, assigned a location, and added to the digital model. The number of instances can also be determined. In some embodiments, the digital model generator 614 identifies and extracts the information using one or more artificial intelligence (AI) systems, shown as machine learning agent 640. In some embodiments, the machine learning agent 640 uses optical character recognition (OCR) and other text and image processing techniques to extract the relevant data from the project information that may be included in the digital model. In some embodiments, machine learning agent 640 is configured to create a model such as an artificial neural network (ANN), decision tree model, a support-vector machine, a regression analysis, Bayesian network, or other machine learning models known in the art. Various inputs may be supplied to the model as described herein. In some embodiments, the extracted information is used to build the digital model representing the project.

In some embodiments, the digital model generator 614 saves the extracted schedules, schedule notes, floor plans, and equipment tags as a digital model of the building. The digital model may include one or more zones, rooms, and/or floors corresponding to one or more zones, rooms, and/or floors in the building as indicated by the MEP blueprints. Each extracted schedule, schedule note, floor plan, and equipment tag may include information regarding its location in the MEP plans (i.e., sheet number) as well as its corresponding location in the digital model (e.g., zone, room, floor). The location information may be derived from a position on a sheet which correlates to a zone, room, and/or floor. In some embodiments, the position includes a sheet identification and a set of coordinates (x and y) indicating the location of the information on the sheet. In some embodiments, the digital model generator 614 is configured to identify each instance of an equipment tag in the project information and organize them by location in the digital model. For example, the digital model generator 614 may organize extracted equipment tags by floor. In some embodiments, the digital model generator 614 is configured to associate each extracted schedule with one or more equipment tags. For example, the digital model may tie an equipment tag to a corresponding schedule with details and desired performance characteristics for the building equipment component represented by the equipment tag.

In some embodiments, the digital model generator 614 may be configured to allow a user to modify the digital model. For example, the digital model generator 614 may mistakenly identify a sample of text as an equipment tag. A user may update the model by removing the mistaken equipment tag from the model. Once removed, the equipment tag would remain in the project information, but no longer be integrated into the digital model. In some embodiments, the digital model generator 614 may be configured to reconstruct the digital model after a modification by a user. For example, a user may change the floor associated with a floor plan. Digital model generator 614 can then reprocess the project information to ensure the entire digital model is updated. This may include, for example, re-identifying and extracting equipment tags from the floor plan that was moved so that the location of the equipment tags in the digital model is updated to correspond with the new floor as indicated by the user.

In some embodiments, project configurator 616 is configured to receive the digital model and use the digital model to select building equipment components for the project. The project configurator 616 may access building equipment database 622 to obtain a list of available components and associated equipment configuration data (e.g., labor costs, material costs, installation costs, sell prices, complexity quantifiers, etc.). Project configurator 616 may also be configured to filter a preexisting list of components stored within building equipment database 622, or may dynamically generate new components or new combinations of components though communications with machine learning agent 640.

In some embodiments, before selecting specific building equipment components, project configurator 616 may be configured to receive the digital model and calculate performance metrics for one or more identified types of building equipment located in the digital model. For example, the digital model may include a schedule and/or schedule notes for a chiller listing design information and desired performance characteristics for the chiller. The project configurator 616 can be configured to calculate the cooling capacity necessary for a chiller to meet the listed engineering needs. Performance metrics for each type of building equipment found in the project information, for example as indicated by the equipment tags, schedules, or schedule notes may be calculated. In some embodiments, the performance metrics, in addition and/or in place of the design information in the schedules, may be used by the project configurator 616 to identify specific building equipment components (e.g., from building equipment database 622) that meet the engineering needs of the project. In some embodiments, the project configurator 616 utilizes the machine learning agent 640 to select one or more specific building equipment components for the project. In some embodiments, the selected components represent one or a combination of building equipment components that meet the engineering need.

In some embodiments, the project estimator 618 is configured to receive the digital model from the digital model generator 614 and the selected building equipment components from the project configurator 616 and calculate an estimated quote for the project. The quote may be based on the selected building equipment components, the cumulative number of each component required for the project (e.g., as indicated by the schedules and/or the number of instances of an equipment tag) and large-scale external factors. The large-scale external factors may include labor costs, geographic location, project start date, component pricing, component supply, or other information relevant to costs. For example, project configurator 616 may query an online database to identify a current hourly rate and duration for installing a component of the building system, which can be used to estimate the labor cost for installing a component of a building equipment system. In some embodiments, the project estimator 618 generates the quote by providing the digital model, the selected building equipment components and large-scale factors to the machine learning agent 640. The machine learning agent 640 may analyze the information and calculate a quote that may be provided to a receiving party. The quote may include component cost as well as installation cost.

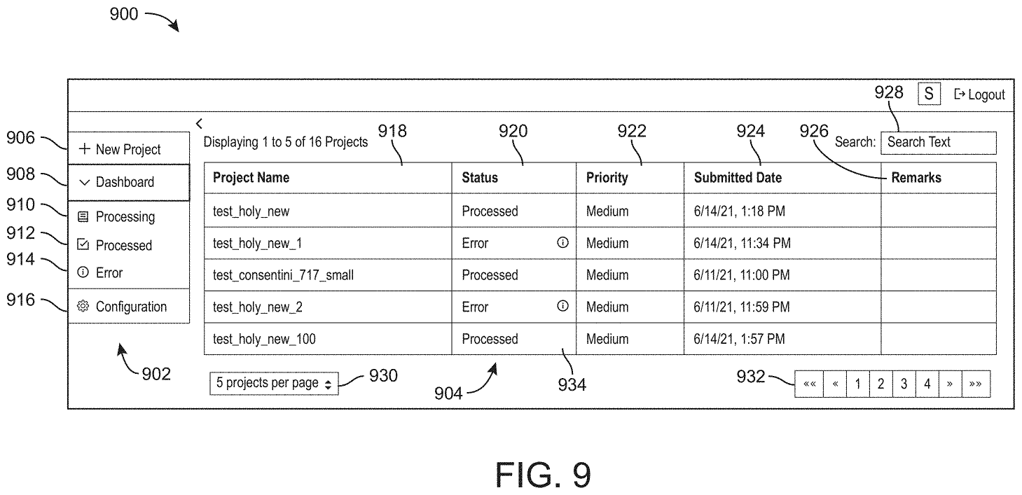

In some embodiments, the memory 610 can also include a graphical user interface (GUI) generator 620 configured to generate one or more user interfaces. These user interfaces can provide any sort of information, both text-based and visually, to a user via user device 650, for example. Example GUIs shown below with respect to FIGS. 9-21 can include a configuration interface that allows a user to input project information for generating a digital model and selecting suitable building equipment components. In some embodiments, GUI generator 620 can also present interfaces that simultaneously present the extracted information included in the digital model overtop the raw, project information it was extracted from to facilitate user review and modification. For example, the GUI generator 620 may display a sheet of the MEP drawings in a base layer, and provide one or more model objects overlaid on top of the base layer in a model layer. The model objects may indicate each identified instance of a schedule, floor plan, or equipment tag stored in the digital model for that sheet. The model objects may be positioned on the user interface in relation to the blueprints in the base layer according to the position of the schedule, schedule notes, floor plan, or equipment tag the model object represents. In some embodiments, the position of the model object corresponds to a position on top of the base layer.

The GUI generator 620 may be configured to present user interfaces designed to account for the complexity and information density of MEP blueprints, especially when presented digitally. As described above, project specifications and drawings (i.e., MEP blueprints) may contain an immense amount of information, such as indications of equipment type and location (e.g., equipment tags) for all HVAC equipment in a floor of a building. In order for such information to be presented on individual sheets, the details are often condensed, and it may be difficult for a user to view an entire sheet and still be able to read the included information. For example, when printed, it is common for sheets to be as large as 18″×24″ and 24″×36″ in order for the details within the sheets to be printed legibly. As sheets are now often delivered and rendered digitally, most displays are simply unable to render the minute details while displaying an entire sheet. In order to render the details, a user must enlarge the portion of the sheet they are interested in, but this forces the user to sacrifice what might be a desirable, sheet-wide view. Conversely, in order for a user to view the entire sheet, they may have to sacrifice the ability to read the details on the sheet. While higher resolution displays may be able to render the detail, there is a physical limit to what the eye can perceive that cannot be overcome with better screens. The GUI generator 620 may be configured to generate user interfaces that account for the inability of most screens to simultaneously display an entire sheet and render the details legibly by providing both a view of the entire sheet or a portion thereof and a summary of the information extracted from the view and stored in the digital model. For example, a user interface may include a view of a floor plan and a sheet summary table of each equipment tag identified in the view and the number of instances of each equipment tag that were identified. When a user zooms into a section of the floor plan, the sheet summary tables provides the sheet-level context that could otherwise not be obtained. Relatedly, if a user is viewing an entire sheet such that the screen is unable to render identified equipment tags legibly, the sheet summary table allows a user to nonetheless view the relevant, extracted sheet information contained in the digital model even though the source equipment tags in the sheet are unreadable.

In some embodiments, memory 610 includes a building equipment database 622 configured to store parameters and information for a wide variety of possible building equipment system components, such as performance metrics, sell prices, labor cost information, material cost information, installation cost information, product configuration information (e.g., type of air handling unit, air flow rate, damper settings, controller settings, etc.). In some embodiments, building equipment database 622 is regularly or continuously updated with data from remote systems (e.g., product manufacturer databases, retail databases, cost databases, etc.), via network 660 and/or data from machine learning agent 640. In some embodiments, building equipment database 622 includes preconfigured building equipment system component relationships and combinations.

In some embodiments, memory 610 includes a project database 624 configured to store prior project data. In some embodiments, the prior project data is a set of previous digital models, building equipment component selections and quotes by the configuration tool 600. In some embodiments, the set of prior project information is a set of manually entered quotes and selections from past projects. In some embodiments, project database 624 stores equipment configuration data. In some embodiments, equipment configuration data is a product weight, power requirement information, performance information (e.g., power curves, rise times, sensitivities, etc.), component input information, component output information, reliability information, maintenance schedules, product dimensions (e.g., length, width, height, etc.), various connection and coupler requirements (e.g., mechanical couplers, electronic couplers, controls circuit requirements, etc.), and still other suitable configuration data for designing a building system using the component.

In some embodiments, project database 624 is partially or fully populated by machine learning agent 640. For example, a prior project may be missing several categories of information (e.g., labor costs, engineering hours, etc.) and machine learning agent 640 may identify one or more patterns in the prior project data to artificially populate the missing fields. In some embodiments, project database 624 receives updated project information from network 660 and may supply prior budget information to machine learning agent 640. Although machine learning agent 640 is shown as separate from configuration tool 600 in FIG. 6, it should be understood that machine learning agent 640 may be a component of configuration tool 600 and/or project planning tool 612 in some embodiments.

In some embodiments, the project database 624 includes data that includes a plethora of prior project information attributes including a prior project's vertical market information, locale information, product preferences, components used, components selected, client information, payment information, billing information, profit margins, estimated project duration, actual project duration, contractors and subcontractors used, components selected for the estimate, components actually installed on the worksite, labor rates, equipment costs, installation costs, engineering notes, installer notes, and other project specific information.

Still referring to FIG. 6, configuration tool 600 is shown to include a communications interface 630 for facilitating communications between configuration tool 600 and any number of external devices or system. As shown, for example, interface 130 can facilitate communications between configuration tool 600, network 660, user device 650, and machine learning agent 640, as described in greater detail below. Communications interface 630 can be or can include wired or wireless communications interfaces (e.g., jacks, antennas, transmitters, receivers, transceivers, wire terminals, etc.) for conducting data communications. In some embodiments, communications via communications interface 630 can be direct (e.g., local wired or wireless communications) or via a communications network (e.g., a WAN, the Internet, a cellular network, etc.). For example, communications interface 630 can include an Ethernet card and port for sending and receiving data via an Ethernet-based communications link or network. In another example, communications interface 630 can include a Wi-Fi transceiver for communicating via a wireless communications network. In another example, communications interface 630 can include cellular or mobile phone communications transceivers. In one embodiment, communications interface 630 is a power line communications interface.

In various embodiments, network 660 is any suitable network for transmitting and receiving data with remote devices and systems. For example, network 660 may be any type of intranet or internet such as a local area network (LAN), a wide area network (WAN), a virtual private network (VPN), etc. In some embodiments, any number of other remote systems or devices may be communicably coupled to network 660 such that the remote systems and devices may communicate with configuration tool 600. As an example, a remote server or computing system may be coupled to network 660 and may handle a portion of the processing or storage required by configuration tool 600.

User device 650 may be any electronic device that allows a user to interact with configuration tool 600, such as through a user interface. Examples of user devices include, but are not limited to, mobile phones, electronic tablets, laptops, desktop computers, workstations, and other types of electronic devices. Accordingly, user device 650 generally includes a user input device such, such as a keyboard, a touchscreen display, a keypad, buttons, switches, etc. User device 650 may present a graphical user interface on a display and receive user input via the user input device, thereby enabling a user to easily and intuitively interact with configuration tool 600.

Referring now to FIG. 7, a flow diagram of a process 700 for generating a digital model from project information is shown, according to an exemplary embodiment. Process 700 may be performed by one or more components of configuration tool 600 and/or other components shown in FIG. 6. Various examples of user interfaces that can be generated and presented to a user to facilitate some or all of the steps of process 700 are described in greater detail below with reference to FIGS. 9-20.

Process 700 is shown to include receiving project information including blueprints (i.e., project specifications and drawings, MEP blueprints, etc.) for the building (step 702), obtaining/configuring a tag dictionary of potential tag identifiers (step 704), generating a digital model of the building (step 706), displaying a base layer including a portion of the blueprints and a model layer including a portion of the digital model (step 708), receiving a user input modifying an aspect of the digital model (step 710), updating the digital model based on the user input (step 712), and displaying a base layer including a portion of the blueprints and a model layer including a portion of the updated digital model (step 714).

At step 702, project information including blueprints for the building is received by configuration tool 600. In some embodiments, the project information includes a project name, a primary contractor, and/or MEP blueprints of the building. In some embodiments, the project information is received via communications interface 630 from user device 650. The MEP blueprints may include one or more sheets of blueprints. Each sheet may include one or more schedules, schedule notes, floor plans, or detail views of a portion of the building. Each sheet may include multiple instances of various equipment tags indicating a type of building equipment and its location in the building.

At step 704, a tag dictionary of potential tag identifiers is received. In some embodiments, the potential tag identifiers are alphanumeric strings indicating that a proceeding, or following (e.g., related) alphanumeric string is an equipment tag. For example, a potential tag identifier “tag no.” may be a column header in schedule, which configuration tool 600 may be configured to understand indicates that the items listed in the column are equipment tags, such as “LDSA”. In some embodiments, the list of potential tag identifiers is populated by an AI system, such as machine learning agent 640. For example machine learning agent 640 may review one or more prior projects located in project database 624 and identify commonly occurring tag identifiers that should be searched for in the new project.

In some embodiments, a user may edit the list of potential tag identifiers in the tag dictionary, including adding a new tag identifier, deleting a pre-existing tag identifier, or modifying a pre-existing tag identifier. For example, a user may be aware that engineers in a certain geographic region use a unique tag identifier, and can add that tag identifier to the list of potential tag identifiers.

In some embodiments, in addition to containing a list of potential tag identifiers, the tag dictionary may include a list of potential sheet identifiers and/or a list of potential floor plan identifiers. Potential sheet identifiers provide information on the type of sheet being analyzed, and may be used for determining where in the digital model information obtained from the sheet belongs. In some embodiments, the potential sheet identifiers identify the type of sheet (i.e., “plan”, “layout,” “level,” “floor,” “schedule,” etc.). Potential floor plan identifiers may be used to indicate to the configuration tool 600 the sheet includes a floor plan. Potential floor plan identifiers may include “floor,” “plan,” etc. and indicate that the proceeding value, for example a “5” after “floor” is the floor in the building the sheet corresponds to. In some embodiments, a user may modify the list of potential sheet identifiers and floor plan identifiers in a manner similar to the list of potential equipment tag identifiers.

In some embodiments, the digital model of the building is generated by using AI systems, such as machine learning agent 640. The digital model may be based on the project information (e.g., MEP plans) and the building layout and all identified schedules, schedule notes, floor plans, and instances of equipment tags. In some embodiments, the identified schedules, schedule notes, floor plans, and equipment tag instances are identified using the tag dictionary. Identified information is extracted from the MEP blueprints and added to the digital model of the building. In some embodiments, the identified information is added to a location in the digital model corresponding to its location in the building as indicated by the MEP blueprints. For example, equipment tags on a sheet identified as belong to Floor 5 of building may be added to a corresponding Floor 5 of the digital model. The identified information may also include the location in the original MEP blueprints of each piece of identified information. For example, the same equipment tags may be associated with sheet M5.01. In some embodiments, the location may be directly tied to the location on a floor plan of sheet. In some embodiments, the digital model is generated by performed OCR on the project information and storing the information in the digital model in computer readable/editable forms. For example, a schedule may be extracted and converted into a tabular format suitable for a user to edit via the user device 650. In some embodiments, the digital model includes a count of the total number of instances of each equipment tag by sheet and in the MEP plans as a whole. In some embodiments, a user may run a report on the digital model requesting information derived from the identified schedules, floor plans, and equipment tags. For example, a user may request a report indicating the number of “LDSA” tags on Floor 5 of the digital model.

At step 708, process 700 includes displaying a base layer including a portion of the blueprints and a model layer including a portion of the digital model. For example, GUI generator 620 may be configured to generate a user interface for display on user device 650 of at least a portion of the blueprints in a base layer and the digital model overlaid on top of the blueprints in a model layer. In some embodiments, the portion is a sheet of the blueprints. In some embodiments, the portion is merely a segment of a sheet. A user may be allowed to adjust the segment of the sheet displayed, including zooming in to view in detail a segment, and zooming out to an entire sheet. In some embodiments, overplayed on top of the portion of the sheet in a model layer is one or more model objects that provide a visual indication of the data in the portion which is included in the digital model. For example, the portion may include a “LDSA” equipment tag. The “LDSA” equipment tag on the sheet can be overlaid with a model object which highlights the equipment tag indicating that it is identified a part of the digital model. This allows a user to see both the original project information in the base layer, as well as which portions of it were automatically identified and added to the digital model by the configuration tool 600 in the model layer. Such a display facilitates user review of the digital model generation process and assists a user in working the MEP blueprints digitally.

In some embodiments, in addition to displaying the portion of the blueprints in a base layer and the digital model overlaid on top in a model layer, the user interface may also include one or more tables containing other relevant information derived from the digital model. The information in the tables may relate to the entire sheet and/or building, and not just the visible portion on the user interface, allowing a user to view details on the MEP blueprints while still providing them a view of the relevant information sheet-wide. Allowing for sheet-wide information to be available no matter the segment of the sheet being viewed may compensate for the inability of a display to legibly render the details in a sheet when viewing the entire sheet once. Instead, the details that were extracted and stored in the digital model may be presented in a legible form next to the source project information, allowing a sheet-wide view while maintaining legibility of the relevant information. For example, a user maybe viewing a segment of a sheet with only one equipment tag “LDSA,” but a sheet summary table may include a count of all instances of the equipment tag “LDSA,” on the entire sheet. Relatedly, a user may be viewing an entire sheet and unable to read equipment tags, but a sheet summary table may include a summary of all equipment tags found on a sheet and the number of instances of each tag.

At step 710, a user may modify an aspect of the digital model. In some embodiments, using the user interface displaying a portion of the blueprints and the digital model, a user may review the construction of the digital model, and add, remove, or update the information within it by interacting with the model objects in the model layer. For example, a schedule included in the digital model may not be relevant to a user, and the user may remove the schedule from the digital model by selecting and deleting the model object representing the schedule. Where the schedule was previously highlighted on the portion of the blueprints by a model object, it may no longer be highlighted, indicating it is no longer included in the digital model. In some embodiments, a user may modify information contained in the digital model. For example, an identified schedule may include column headers that a user may wish to modify for local custom. The user may edit the column headers in the digital model by interacting with a table presented on the display of the extracted information from the schedule. In some embodiments, the user may modify a portion of the schedule yet retain the rest of the information in the schedule, allowing the digital model to be modified in a piecemeal fashion. Modifications by a user may result in changing the content of a schedule, editing an equipment tag, associating a sheet and any schedules, floor plans, and equipment tags it contains with a different floor, retitling a sheet, renumbering a sheet, reducing the size of schedule to only essential information, adding a formerly unadded schedules, floor plans, and/or equipment tags, removing formerly added schedules, floor plans, and/or equipment tags, modifying a schedule type, map essential columns for a schedule to column in an extracted schedule, append a prefix to an equipment tag, import schedule table structures, export schedule tables, add floor/typical sheets, delete sheets, adjust detected floor plan area, change drawing type (e.g., typical, not typical), add unique identifier for a typical, and more.

At step 712, the digital model is updated based on the user modification. In some embodiments, a single user modification may propagate in a one-to-many manner when digital model is updated. For example, after a user appends a prefix to an equipment tag by modifying the model object of the equipment tag (such that the model object is modified, but the blueprint in the base layer remains unmodified). In updating the digital model the configuration tool 600 may append the prefix to each instance of the equipment tag in the digital model. For another example, if a sheet is added to a different floor, the updated model can update the floor for all information extracted from the sheet in the digital model. In some embodiments, updating the digital model includes reprocessing and re-identifying the equipment tags in the blueprints.

At step 714, a base layer including a portion of the blueprints and a model layer including a portion of the updated digital model is displayed. The user interface allows a user to review the digital model in the model layer and the blueprints in the base layer simultaneously. This can allow a user to see changes which have propagated, for example equipment tags in the digital model which are different than the equipment tags in the blueprints they were originally derived from. Similar to step 708, the user interface may also display one or more tables summarizing information identified in the presently displayed sheet and/or the entire blueprints. Such tables may include information on equipment tags, the number of instances of equipment tags, tabulated schedules, thumbnails of other sheets in the blueprints, etc. In some embodiments, the additional information displayed is in the form of model objects overlaid on top of the portion of the blueprints in a model layer. The model objects may include visual indications such as bounding boxes, highlights, colored overlays, transparent overlays, arrows, and/or other graphical and textual indications of an additional layer of information on top of the source project information.

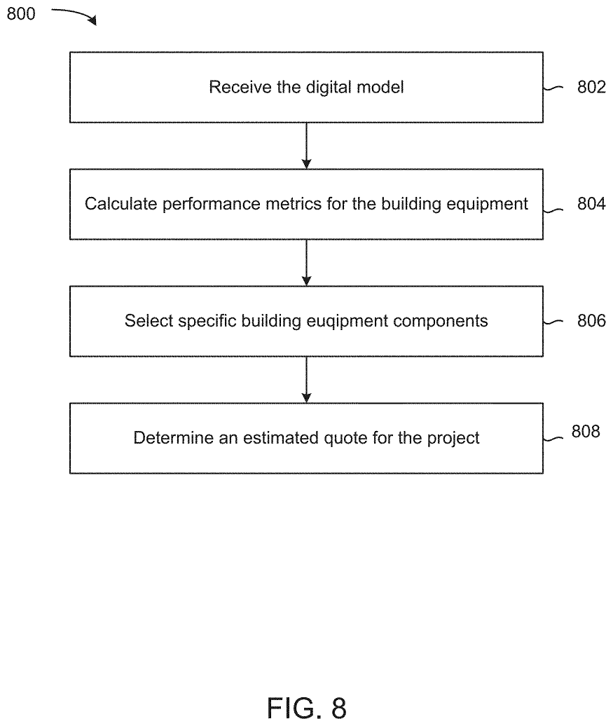

Referring now to FIG. 8, a flow diagram of a process 800 for generating a quote for the project based on the digital model is shown, according to an exemplary embodiment. Process 800 may be performed by one or more components of configuration tool 600 and/or other components shown in FIG. 6.

Process 800 is shown to include receiving the digital model (step 802), calculating performance metrics for the building equipment in the digital model (step 804), selecting specific building equipment components based on the digital model and the performance metrics (step 806), and determining an estimated quote for the building based on the specific building equipment components selected (step 808).

At step 802, the digital model is received. For example, in configuration tool 600 the digital model may be received by the project configurator 616 from the digital model generator 614. In some embodiments, the digital model includes extracted schedules, schedule notes, floor plans, and equipment tags. The digital model may further include location information identifying the location of each extracted piece of information in the digital model (e.g., wall, room, zone, floor, etc.). In some embodiments, the digital model further includes links/associations between equipment tags, schedules, and schedule notes. For example, a tag for an AHU unit may be linked to a schedule indicating the AHU tag and various design specifications for required AHUs.

At step 804, performance metrics for the various identified types of building equipment are calculated. In some embodiments, one or more schedules, schedule notes, and/or equipment tags may be identified as belonging to an equipment type (e.g., chiller, AHU, RTU, VAV, etc.). The schedules and/or schedule notes can include equipment requirements and design details indicating the engineer's performance and/or physical requirements for the building equipment. For example, a schedule may include a unit size, a horsepower for a motor, a cooling capacity, a face area, a gallons per minute requirement, and/or any other equipment specifics that may be used to identify the engineering needs for building equipment in a specific project. Using the information in schedule, and/or the number of pieces of equipment needed as indicated by the number of instances of an associated equipment tag identified in the project information, performance metrics can be calculated for the building equipment type. In some embodiments, performance metrics are a better indication to use for selecting specific building equipment components than general design specifications found in a schedule. In some embodiments, performance metrics are only calculated for some of the building equipment types identified in the project information. Still, in some embodiments, the information in the schedules is used directly, and step 804 is skipped and process 800 proceeds directly to step 806.

At step 806, specific building equipment components are selected based on the digital model and/or the calculated performance metrics. In some embodiments, an artificial intelligence system, such as machine learning agent 640, selects the specific building equipment from a data base of building equipment, such as building equipment database 622. The specific building equipment is selected to satisfy the requirements included in the digital model, such as in the identified schedules or schedule notes, and/or to meet the performance metrics. The specific building equipment components selected may also be based on large scale factors. Large scale factors may include market considerations such as installation costs, product availability, component price, component quantity, etc. Large scale factors may also include geographic specific costs such as labor or weather. In general, large scale factors may be any information related to the project and/or derived from past projects (e.g., by machine learning agent 640) that may affect the specific building equipment chosen. In some embodiments, a user may select specific preferred equipment components, deselect unwanted components, and otherwise modify the list of selected specific components. Based on the user input, the list may be updated with new components that nonetheless meet the engineering needs. In some embodiments, a set of rules may dictate the equipment selection process. The rules may be received from a remote system. In some embodiments, the rules are provided by a user prior to the process.

At step 808, an estimated quote based on the selected specific building equipment components is generated. In some embodiments, the quote is provided to a user for view. The user may review and modify the quote. In some embodiments, the quote is automatically provided to a requesting party. For example, a user may supply a primary contact for a project. The configuration tool 600 may receive the project information, analyze the project specifications and drawings to create a digital model of the project, select specific building equipment components that meeting the engineering needs represented in the digital model, generate a quote for the building equipment, and automatically provide the quote to the primary contact.

Referring now to FIGS. 9-20, various user interfaces for interacting with a configuration tool 600 are shown, according to exemplary embodiments. The user interfaces 900-1900 may be displayed in response to a user input login credentials to the configuration tool 600.

Referring specifically to FIG. 9, a user interface 900 includes a sidebar, shown as sidebar 902, and a project information area shown as project area 904. In some embodiments, project area 904 includes a table of existing projects 934. The table of existing projects 934 may include columns including the project name 918, the status 920, the priority 922, the submitted date 924, and any user remarks 926. In some embodiments, the project status 920 provides an indication if a project is processing, is processed, or if an error has occurred. An error may be included an indication of the type of error. In some embodiments, the priority 922 may include a series of rankings such as low, medium, or high. The submitted date 924 indicates the date each project may need to be submitted with a bid to a requesting party. In some embodiments, a user may select a column header in table of existing projects 934 and sort the projects in the table by the selected column.

In some embodiments, the sidebar 902 has one or more user selectable options, including selections for a new project 906, a dashboard 908, and a configuration tab 916. In some embodiments, the dashboard 908 reveals a sub-menu of options including processing 910, processed 912, and error 914. The sub-menu of options in dashboard 908 may correspond to the status options in status 920 column, and allow a user to filter projects by status types. A user selecting one of the sub-menu tabs 910-914 may be presented with a table of existing projects 934 of projects according to the selected status.

In some embodiments, a search box 928 is provided on user interface 900. A user may search for projects by project name using search box 928. User interface 900 is also shown to include display selector 930 which is configured to set the number of projects visible per page in the project area 904. As shown in user interface 900, there are 5 projects per page displayed, though this can be changed to 10, 15, 20 25, etc. In some embodiments, user interface 900 also includes a page selector 932 for navigating amongst the pages of table of existing projects 934.

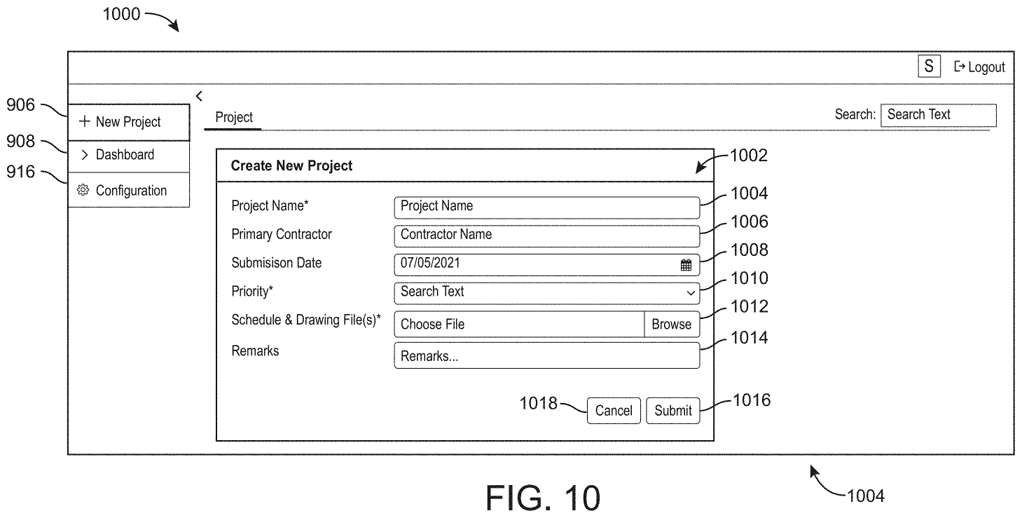

Referring now to FIG. 10, a user interface 1000 is shown, according to an exemplary embodiments. User interface 1000 may have one or more features similar to user interface 900. User interface 1000 may include more or fewer selectable options that user interface 900. User interface 1000 may have some or all of the features of user interface 900. Likewise, user interface 900 may have some or all of the features of user interface 1000. The configuration tool 600 can be configured to display interface 1000 based on the input entered by the user via user interface 900 if selecting the new project 906. User interface 1000 includes a create new project input field 1002 displayed in project area 904. The create new project input field 1002 includes identifying information for a project that may be displayed in the table of existing projects 934 shown in FIG. 9. Interacting with the create new project input field 1002 a user can input project information in fields for a project name 1004, a primary contractor 1006, a submission date 1008, a priority 1010, and remarks 1014. A user may also select one or more documents to upload as schedule and drawing files 1012.

In some embodiments, the documents include project specifications and drawings such as blueprints for a project including mechanical, electrical, and plumbing (MEP) blueprints. MEP blueprints can include schedules, schedule notes, floor plans, and details for a project including all the information necessary to select specific equipment that meets the engineering needs of the building. In some embodiments, the MEP blueprints include documents with one or more sheets of engineering drawings. Each sheet may be labeled with a sheet type, a floor number, and other identifying information. Schedules and schedule notes may include operating characteristics and requirements for one or more pieces of building equipment called out in the MEP blueprints, including details for one or more pieces of building equipment as indicated by equipment tags.

Each equipment tag may represent a type of building equipment, and there may be multiple instances of each equipment tag in the project and/or on each sheet. Floor plans may include one or more building tags indicating the position of the building equipment in the building. Each sheet can contain multiple instances of multiple equipment tags. In some embodiments, the schedule and drawing files are provided by the party requesting a quote for the specific building equipment that meets the engineering needs of the building as identified in the MEP blueprints. Upon selecting schedule and drawing files 1012 a user may be prompted to select one or more files to import as additional project information. After completing input fields 1002-1014 a user may submit project by selecting submit element 1016 or cancel a project by selecting cancel 1018.

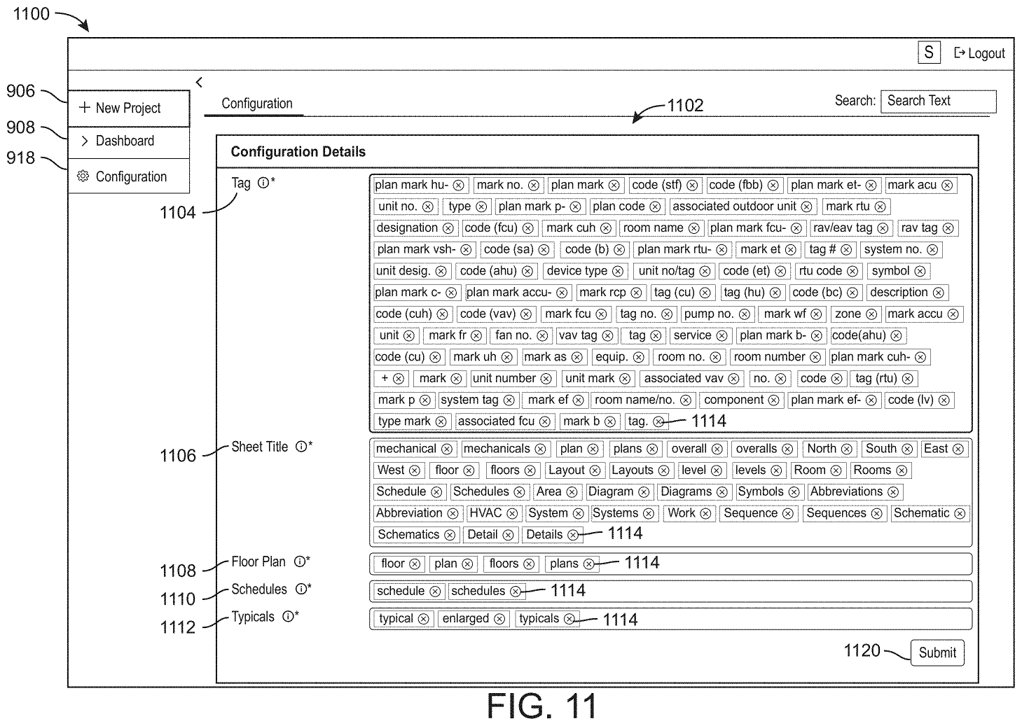

Referring now to FIG. 11, a user interface 1100 is shown, according to exemplary embodiments. User interface 1100 may have one or more features similar to user interface 900. User interface 1100 may include more or fewer selectable options that user interface 900. User interface 1100 may have some or all of the features of user interface 900. Likewise, user interface 900 may have some or all of the features of user interface 1100. The configuration tool 600 can be configured to display interface 1100 in response to a user selection of the configuration tab 916 in sidebar 902 and or the submit element 1016. User interface 1100 includes configuration details 1102 for processing the current project. In some embodiments, the configuration details include one or more lists of potential tag identifiers divided by type, including tag identifiers for equipment tags in tag field 1104, tag identifiers for sheet tags shown in sheet title field 1106, tag identifiers for floor plan tags shown in floor plan field 1108, tag identifiers for schedule tags shown in the schedule field 1110, and tag identifiers for typical sheets shown in typicals field 1112.

The various tag identifiers in tag field 1104 may be a list of potential tag identifiers 1114 that will be searched for in the project information, such as the MEP blueprints. In some embodiments, the tag identifiers in the tag field 1104 represent a list of potential tag identifiers obtained from a tag dictionary, such as tag dictionary 626. Each potential tag identifier 1114 may be an alphanumeric string commonly associated with an equipment tag. The various tag identifiers 1114 listed in fields 1104-1112 will be searched for in the project information to identify and extract desired information such as equipment type, sheet number, floor number, schedules, typicals etc. User interface 1100 includes an option to delete a tag (x icon) 1116. In some embodiments, a user may select in area 1118 and enter a new potential tag identifier 1114. In such a manner a user may modify the list of potential tag identifiers 1114 in fields 1104-1112.

In some embodiments, the various tag identifiers 1114 are generated by a machine learning agent, such as machine learning agent 640. Machine learning agent 640 may populate the fields 1104-1112 with tag identifiers 1114 derived from past projects that have been found to be commonly used are may be associated in some manner with the current project. Still in other embodiments the tag dictionary is generated according to the primary contractor or another aspect of the project information.

Interacting with the submit element 1120 a user can begin processing the project using the tag dictionary. Specifically, configuration tool 600 may be configured to generate a digital model of the building based on the supplied information. Generating the digital model may include a search of the project information for the various tag identifiers 1114 from fields 1104-1112 and identifying the corresponding tag information including equipment tags, sheet number, schedule, schedule note, schedule type, sheet type, etc. In some embodiments, the project is processed according to process 800. Processing may involve performing one or more image processing techniques to identify tag identifiers in the project and their associated tag information (i.e., equipment tags, sheet numbers, sheet titles, etc.), in addition to identifying schedules, schedule notes, floor plans, and details in the MEP blueprints. In some embodiments, the configuration tool 600 is configured to provide the project (including the MEP blueprints) to the machine learning agent 640 for processing. In some embodiments, each piece of identified information is associated with its location in the MEP blueprints. For example, an equipment tag may be associated with a specific sheet, and in some embodiments its exact location on the specific sheet. In some embodiments, each piece of identified information is also associated with a location in the digital model. In some embodiments, piece of identified information (e.g., the floor plan, the equipment tag, etc.) is located in the digital model based on its location in the MEP blueprints. For example, an equipment tag located on a sheet for a first floor may be added to the first floor of the digital model. Accordingly, each piece of identified information is associated at least with both a location of identification in the raw project information and a placement location in the digital model. By correlating each piece of identified information with a location in the digital model.

While generating the digital model, the configuration tool 600 may also generate one or more user interfaces presenting a portion of the project information, for example one sheet of the MEP blueprints, in a base layer, and presenting a corresponding portion of the digital model in a model layer overlaid on top of the base layer. The model layer may include model objects providing a visual indication of the details in the portion that are present in the digital model. The user interfaces may allow a user to compare the digital model with the raw project information to ensure the digital model was processed correctly.

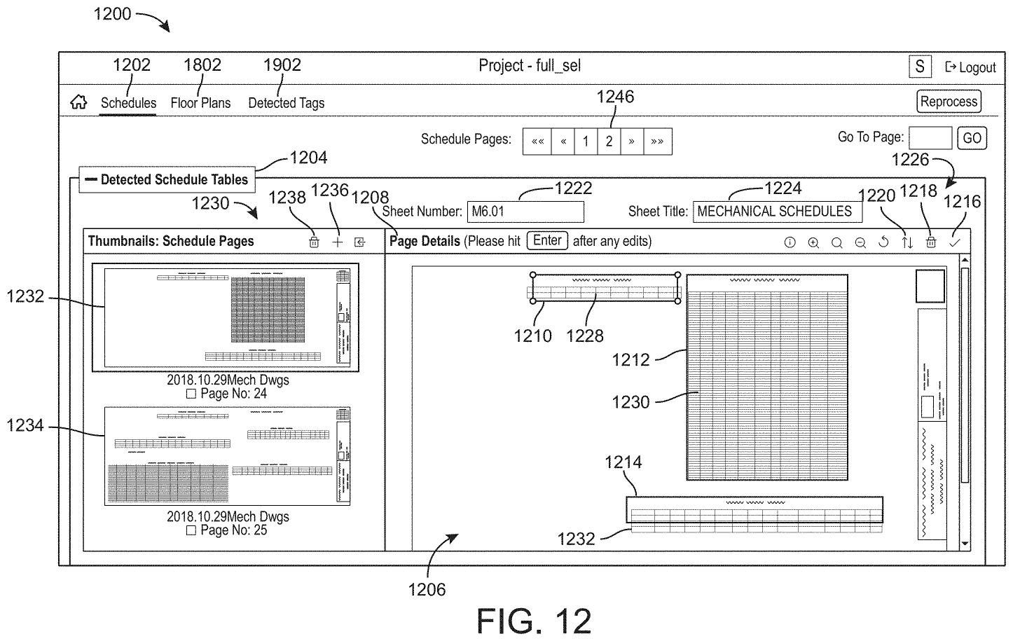

Referring now to FIGS. 12-20, various user interfaces for presenting MEP blueprints and the digital model are shown, according to various exemplary embodiments. The configuration tool 600 can be configured to display the interfaces 1200-1900 based on the input entered by the user via the interfaces 900-1100. The interface 1200 may be displayed specifically when a user selects a processed project in existing projects 934 and/or submits a new project with the submit element 1120.

The interface 1200 is shown to include schedules tab 1202, floor plans tab 1802, and detected tags tab 1902. Interface 1200 is shown with the schedule tab 1202 selected. Schedule tab 1202 is shown to include a detected schedule tables 1204 and/or detected schedule notes. Detected schedule tables 1204 may include a page details pane 1208 displaying a sheet 1206. In some embodiments, the sheet 1206 is a sheet of the MEP blueprints imported by a user. While the entire sheet 1206 is shown in page details pane 1208, in some embodiments only a segment of sheet 1206 may be shown. In some embodiments, the sheet 1206 is shown in a base layer of the user interface 1200 A user may interact with elements in the page details toolbar 1226 to zoom in/out, rotate, and otherwise interact with the sheet 1206 in the base layer. Interface 1200 is shown to include various overlays in page details pane 1208 on top of sheet 1206, including model objects 1210, 1212 and 1214 on top of schedules 1228-1232. In some embodiments, the model objects 1210-1214 are presented in a model layer overlaid on top of the base layer. In some embodiments, the base layer includes information from the blueprints, and the model layer includes information from the digital model. In some embodiments, the model objects 1210-1214 indicate that the schedules 1228-1232 in sheet 1206 were identified and incorporated into the digital model. In some embodiments, a user may be able to modify the information contained in the digital model by interacting with one or more of the model objects 1210-1214. By adjusting the model objects, a user can change which information is included in the digital model. For example, a user may select model object 1210, at which point the size and shape of model object 1210 becomes user adjustable. A user may adjust the size and position of the model object 1210 on the sheet 1206 by selecting and moving the model object 1210. When a user has positioned model object 1210 as desired, the user may select the accept element 1216 (green check mark). If the user wishes to remove the model object 1210, and therefore the information contained within it from the digital model, the user may select model object 1210 and select the delete element 1218 (trashcan icon). In some embodiments, a user may change the type of the identified schedules in the model objects 1210-1214 by selecting the change type element 1220. For example, a user may select change type element 1220 to un-tag the selected model object as a valid schedule in the digital model. In some embodiments, only valid schedules are used when selecting building equipment.

The interface 1200 is shown to include sheet number element 1222. A user may interact with sheet number element 1222 to renumber the sheet. In some embodiments, the sheet number element 1222 is populated automatically based on information in the digital model identified from sheet 1206. However, in some embodiments, a user may wish to adjust the sheet number manually. The interface 1200 is shown to include sheet title element 1224. Sheet title element 1224 may be populated automatically and adjusted manually in a manner the same and/or similar to sheet number element 1222. Interface 1200 is also shown to include page navigator 1240, which allows a user to navigate through the pages in the MEP blueprints that were imported.

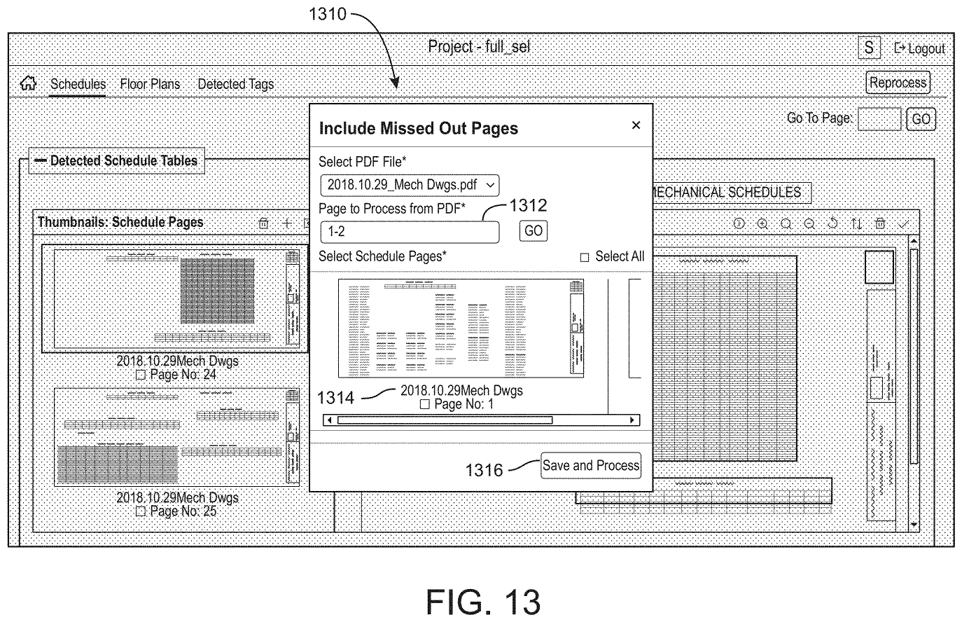

The interface 1200 is shown to include thumbnail pane 1230 including sheet thumbnails 1232 and 1234. In some embodiments, a user may add a missing page to the detected schedule tables 1204 by selecting the add page element 1236 (green plus sign). Referring now to FIG. 13, in response to select the add page element 1236 the configuration tool 600 may request a user to select a document the missing page(s) is located in using page adder 1310 of user interface 1300. Page adder 1310 is shown to include a user selectable page selection element 1312 and page selection interface 1314 the use may use to indicate which page in the selected document contains the page the user desires to add to the project. The user may select multiple pages to add in this manner. Once the desired pages are imported, a user may select the save and process element 1316 to import the pages into the project. In some embodiments, this may include scanning the pages and adding any identified information based on the tag identifiers, including, schedules, floor plans, or equipment tags, to the digital model. Relatedly, a user wishing to delete a sheet from the detected schedule tables 1204 may select thumbnail to be deleted (e.g., thumbnail 1232, 12340) and then the delete page icon 1238 (red trashcan icon).

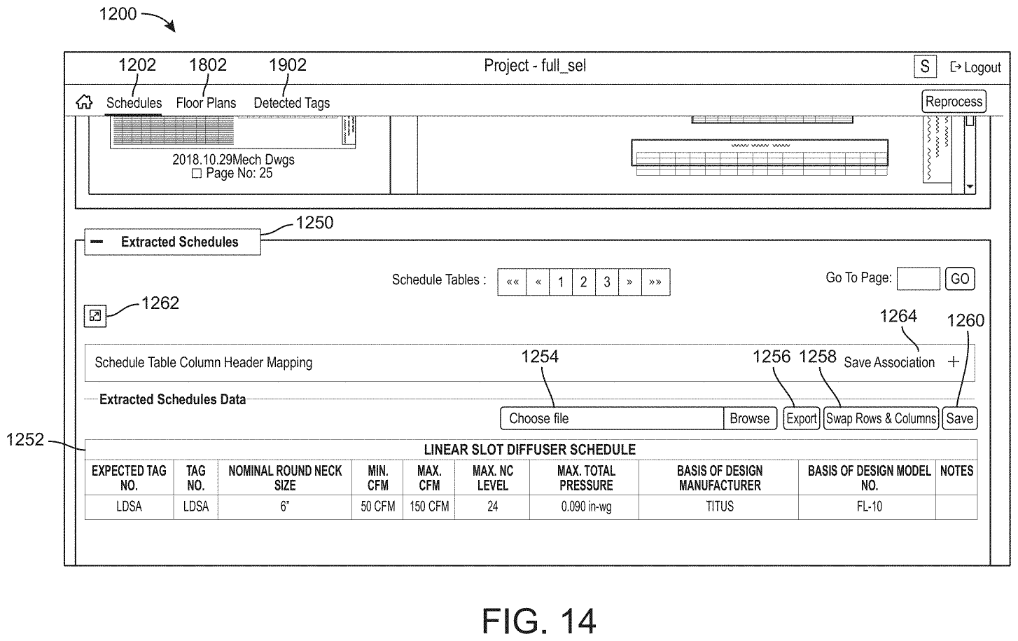

Referring now to FIG. 14, an extended portion of interface 1200 is shown. The extend portion of interface 1200 is shown to include extracted schedules pane 1250. In some embodiments, extracted schedules pane 1250 includes one or more identified schedules 1252 stored in the digital model. Identified schedules 1252 may correlate to one or more schedules indicated to be incorporated into the digital model by model objects 1210-1214. In some embodiments, when generating the digital model the configuration tool 600 may be configured to perform OCR on the schedules in sheet 1206 and identify and extract the schedules and the schedule information. The extracted schedules may be stored in a computer readable/editable form, such as identified schedule 1252. In some embodiments, identified schedule 1252 is user editable. A user may select a cell in identified schedule 1252 and edit the value within it. The updated identified schedules 1252 is then saved in the digital model of the building, which overrides the prior extracted version of the identified schedule 1252 extracted from the MEP blueprints. Interface 1200 is shown with the swap rows and columns element 1258 which may be configured to allow a user to transform a schedule by swapping the rows and columns. In some embodiments, to preserve these or other changes to the identified schedules 1252 a user may select the save element 1260. Schedule notes can be treated the same as the identified schedules 1252.

In some embodiments, a user may import a desired structure/format for the schedule from an external file by selecting the browse element 1254. In some embodiments, a user can export the identified schedule 1252 by interacting with export element 1256.

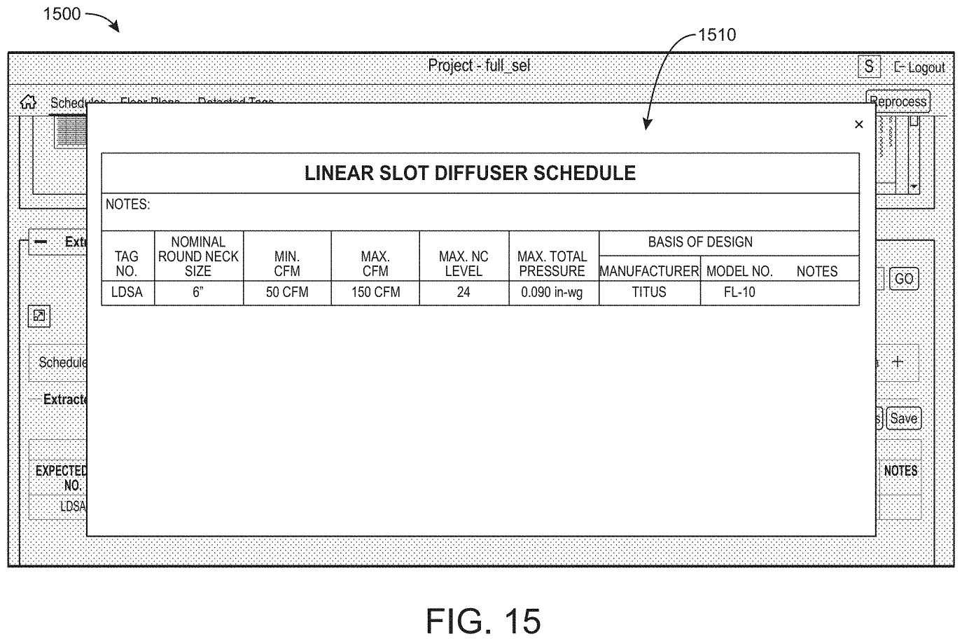

Referring now to FIG. 15, an interface 1500 for viewing the source image 1510 of an schedule is shown, according to an exemplary embodiment. The configuration tool 600 can be configured to display the interfaces 1500 based on the input entered by the user via the interfaces 1200. The interface 1500 may be displayed specifically when a user selects the view source element 1262 in interface 1200 as shown in FIG. 14. In some embodiments, after selecting the view source element 1262 the configuration tool 600 may be configured to present on the user interface the source image 1510 of the identified schedule 1252. As described herein, the identified schedule 1252 is a schedule stored in the digital model of the project that has been extracted from the MEP blueprints. It may be extracted using one or more image recognition techniques, performed, for example, by the machine learning agent 640. A user may wish to view the source of the identified schedule 1252 to determine its accuracy. Configuration tool 600 may be configured to allow a user to view an enlarged source image 1510 from the sheet the identified schedule 1252 is derived from illustrating the source schedule. This may be especially useful on digital user interfaces that may have difficulty rendering smaller details of a sheet while presenting the entire sheet to a user. The enlarged source image 1510 allows a user to view the source image 1510 without having to change the segment of the sheet viewable in details pane 1208.

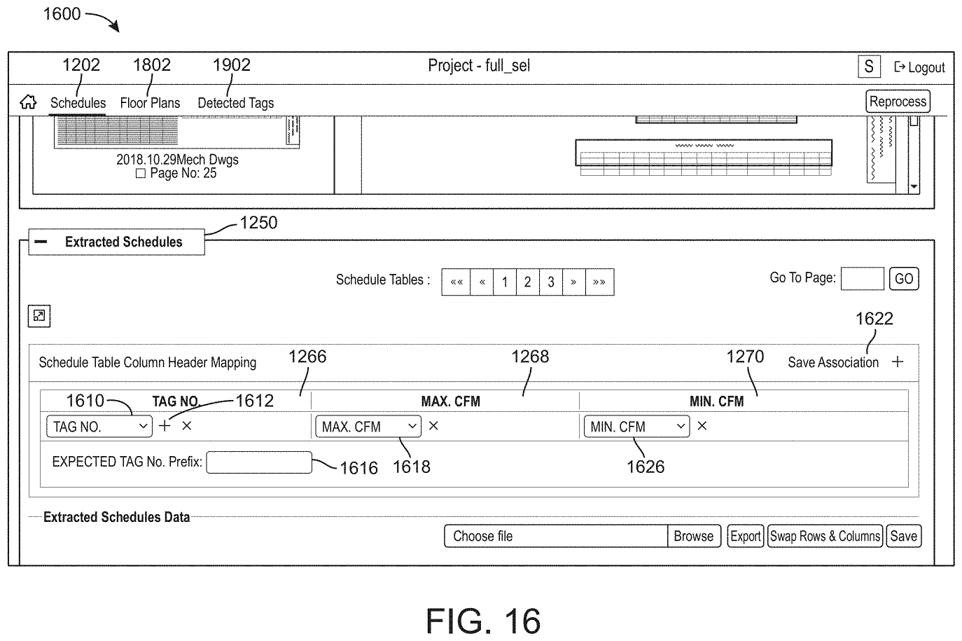

Referring back to FIG. 14, a user may interact with the expand schedule element 1264 to adjust one or more aspects of the identified schedule 1252. In some embodiments, the configuration tool 600 may be configured to display interface 1600 shown in FIG. 16 in response to a user interacting with the expand schedule element 1264. In some embodiments, the expand schedule element 1264 allows a user to adjust and/or map one or more essential columns 1266-1270 to the extracted information from the identified schedule 1252. The essential columns 1266-1270 may be one or more columns of data for a building equipment component that are necessary to size and select specific building equipment components when quoting the project. In some embodiments, the essential columns include the data required to calculate one or more performance metrics for the building equipment components. In some embodiments, the machine learning agent 640 decides which columns are essential for a given building equipment component. Still in some embodiments, one or more rules are provided to configuration tool 600 indicating what information is required for each building equipment component. In some embodiments, an identified schedule in the digital model is reduced to only the essential columns. This removes unnecessary data from the model and may help to streamline the building equipment selection process. In some embodiments, all schedules in the digital model are reduced to their essential columns.

Interface 1600 is shown with tag prefix element 1616. A user may complete the field of tag prefix element 1616 to add desired equipment tag to the schedule. For example, a user may add the tag prefix “RTU”. The configuration tool 600 may be configured to add the “RTU” prefix to each tag no. in the tag no. column of the identified schedules 1252.

Interface 1600 is shown with dropdowns 1610, 1618, and 1620. The dropdowns 1610, 1618, and 1620 may present a list of extracted column values from the identified schedule 1252. A user may select an extracted column value, which maps the extracted column value of the identified schedule 1252. While only three essential column values are shown, there may be more or fewer essential columns. In some embodiments, each column in in a identified schedule is essential for that building equipment component. After selecting one or more extracted column values as essential in the dropdowns 1610, 1618, and 1620, a user may select the save association element 1622 to save the mapping of the essential columns to the columns of the identified schedule 1252.

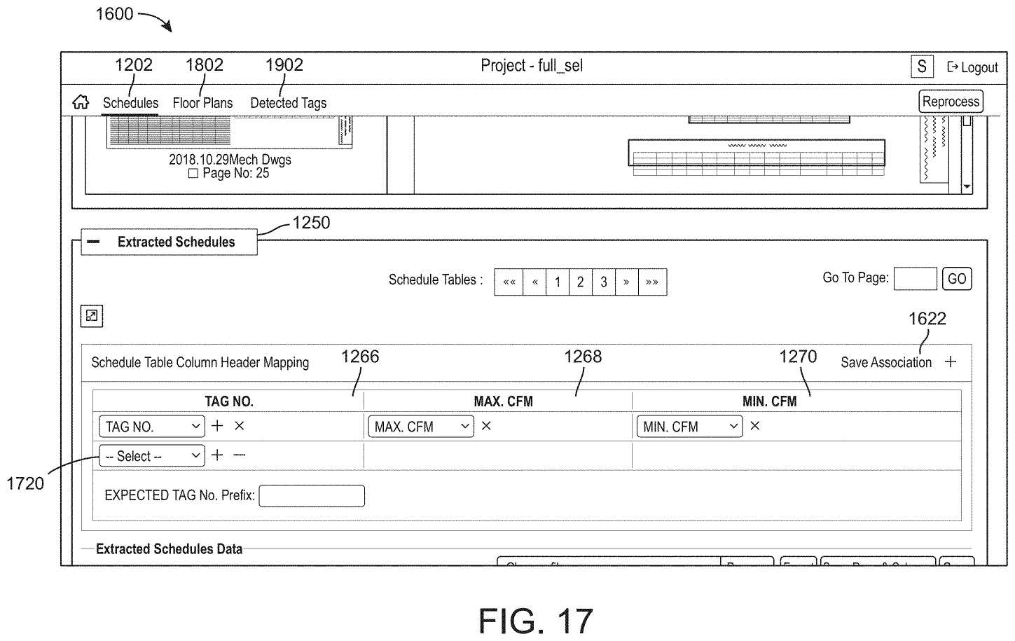

Interface 1600 is shown to include column adding element 1612. In some embodiments, a column of a schedule may be a combination of columns. A user may select column adding element 1612 to add the additional extracted column value to the table. In some embodiments, the configuration tool 600 may be configured to display interface 1700 shown in FIG. 17 in response to a user interacting with the column adding element 1612. User interface 1700 may include more or fewer selectable options than user interface 1600. User interface 1700 may have some or all of the features of user interface 1600. Likewise, user interface 1600 may have some or all of the features of user interface 1700. In response to a user selecting the column adding element 1612 a dropdown 1720 may be presented allowing a user to select an additional extracted column value to present in the identified schedule 1252 present in the digital model.

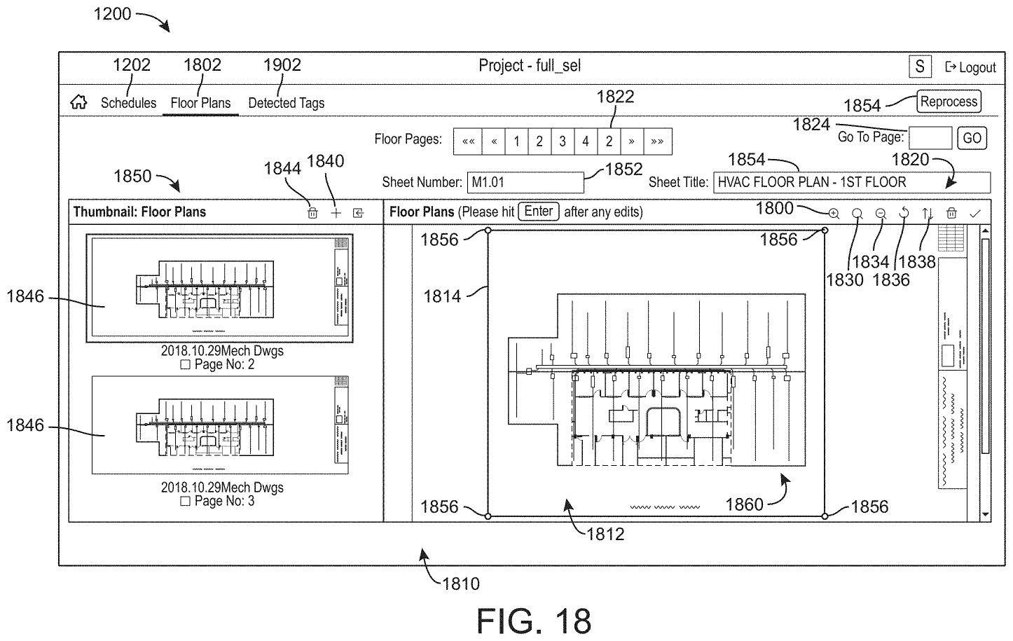

Referring now to FIG. 18, interfaces presenting the floor plans of the MEP blueprints and a digital model for a current project are shown, according to various exemplary embodiments. The configuration tool 600 can be configured to display the interface 1800 based on the input entered by the user via the interfaces 1200-1700. The interface 1800 may be displayed specifically when a user selects the floor plans tab 1802 in interface 1200. Upon selecting the floor plans tab 1802, configuration tool 600 may be configured to present a portion of the MEP blueprints (e.g., a sheet or a segment of a sheet) that has been identified as being a floor plan in a base layer details pane 1810. In some embodiments, overlaid on top of the base layer is one or more model objects 1814, wherein the model objects are presented in a model layer overlaid on top of the base layer. In some embodiments, the user interface of floor plans tab 1802 is similar to the user interface of schedules tab 1202, and may include one or more similar elements.

In some embodiments, portions of the blueprints may be missing from the floor plans tab 1802, and a user may wish to add the missing floor plans to the digital model. A user may select the add page element 1840 to add one or more floor plans. Add page element 1840 may be the same or similar to add page element 1236 shown in FIG. 12. In some embodiments, when adding a page in floor plan tab 1802 a user may be asked to indicate if the page is a typical or a floor plan. A typical is detail drawing of an element that is found multiple times in a set of engineering drawings such as MEP blueprints. Instead of providing multiple drawings of the same element, a typical is often provided as a single reference for the element. A user may also delete one or more floor plans from the digital model by selecting one or more check boxes under thumbnails 1846 in thumbnail pane 1850. After selecting the desired portions of the floor plans (i.e., sheets, thumbnails) to be deleted a user may interact with the delete page element 1844. Interface 1800 is also shown to allow a user to edit the sheet number via sheet number field 1852 and the sheet title via sheet title field 1855.

Interface 1800 includes details pane 1810 presenting a the portion of the MEP blueprints, shown as sheet 1812 in a base layer and a model object 1814 overlaid on top of the sheet 1812 in a model layer. In some embodiments, the sheet 1812 is a floor plan and/or typical automatically identified by the configuration tool 600 and/or the machine learning agent 640. While the entire sheet 1812 is shown in the details pane 1810, a user may enlarge the sheet 1812 to show a section of the sheet 1812 in greater detail by interacting with the zoom in element 1830 of the toolbar 1820. Toolbar 1820 is shown to also include a zoom out element 1832, a rotate element 1836, and a type modifier element 1838. Type modifier element 1838 may allow a user to select if sheet 1812 represents a floor plan or a typical. If a the sheet 1812 is marked as a typical, configuration tool 600 may be configured to request a unique identifier for the sheet 1812. In some embodiments, a user may navigate around the sheet 1812 in the details pane 1810 to view different segments of the sheet. Though shown as displaying a sheet 1812, details pane 1810 may display other portions of the MEP blueprints. A user may interact with page navigator 1822 to select other portions of the MEP blueprints (i.e., other sheets) to view. In some embodiments, a user may proceed directly to a desired portion by interacting with the go to page element 1824.

Interface 1800 is shown with model object 1814 overlaid on top of the floor plan on sheet 1812. In some embodiments, model object 1814 represents to a user digital model, or in some embodiments the portion of the digital model corresponding to the portion of the blueprints presented in the details pane 1810. The perimeter of the model object 1814 may indicate the boundary between details/information located within the model object 1814 which are a part of the digital model, and that details/information located outside the model object 1814 which are excluded from the digital model. In some embodiments, another type of visual indication may be used to represent model objects of the digital model (e.g., transparent overlay, highlight portion, a crop of the sheet 1812, etc.). It should be understood that any graphical element that can inform a user of what information from the sheet 1812 has been identified and extracted may be used as a visual indication.

The combination of the base layer and the model layer allows a user to view the source material, shown as floor plan 1860, and the digital model in sheet 1812 and confirm that the configuration tool 600 has accurately identified and extracted the relevant floor plan information into the digital model. Configuration tool 600 may be configured to allow a user to edit the information in the digital model by interacting with the model object 1814 in the model layer. In some embodiments when sheet 1812 is identified as a typical, a user interacting with model object 1814 may be allowed to add a unique identifier for the typical. In some embodiments, a user may select one or more points 1856 and adjust the size and/or position of the model object 1814. In some embodiments, only the information in the sheet 1812 included within the model object 1814 is included in the digital model. Accordingly, by modifying the model object 1814 a user may modify the digital model.

In some embodiments, after modifying the digital model via the model object 1814, a user may update the digital model by interacting with the reprocess element 1854. Configuration tool 600 may be configured to regenerate the digital model upon a user interaction with the reprocess element 1854. In some embodiments, any modification to the schedules tab 1202 and/or the floor plans tab 1802 may disable the detected tags tab 1902 and enable the reprocess element 1854. In some embodiments, only after reprocessing will the detected tags tab 1902 be enabled again for selection.

In some embodiments, reprocessing may include providing the project information, including the MEP blueprints, to the machine learning agent 640. In some embodiments, regenerating the digital model includes scanning each sheet of the MEP blueprints and identifying schedules, floor plans, and equipment tags based on the tag identifiers located in the tag dictionary. In some embodiments, when re-generating the digital model, this may including searching for an updated group of equipment tags that may have changed based on the modification performed by the user. For example, a user may modify the digital model by shrinking the model object 1814 to cover only a room of a floor plan on sheet 1812. The updated digital model may remove any equipment tags previously found on the sheet 1812 that are now outside of the model object 1814. In some embodiments, the model object 1814 is enlarged by a user, and more equipment tags are added to the digital model. In some embodiments, a user may modify which floor the sheet 1812 is associated with, and when re-generating the digital model the configuration tool 600 may be configured to re-associate each of the equipment tags and/or schedules on the sheet 1812 with the new floor in the digital model. Accordingly, a single modification may result in a multiple changes to the digital model.

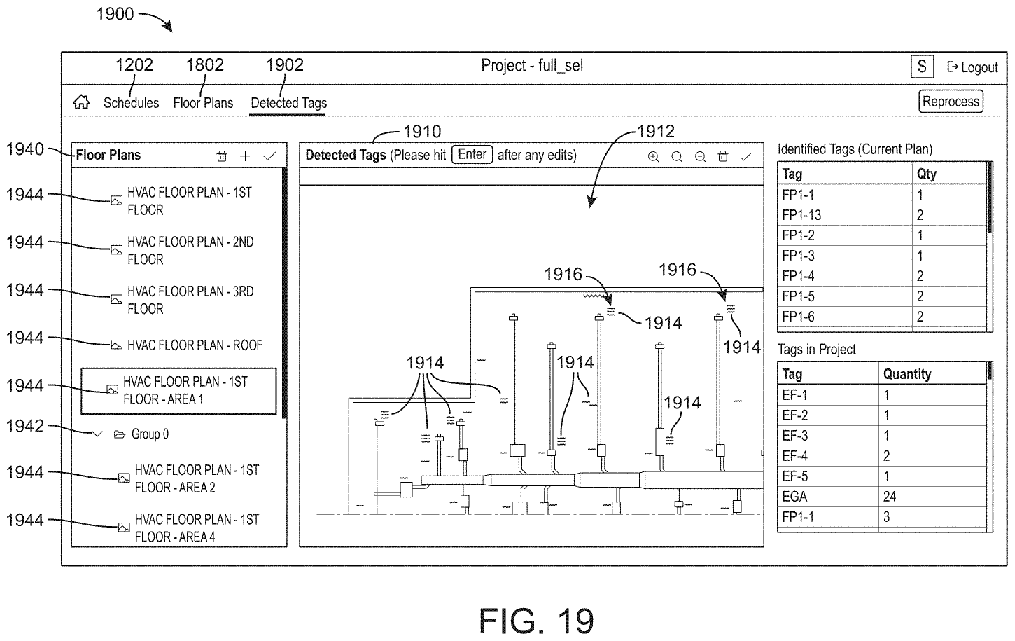

Referring now to FIG. 19, an interface for presenting the floor plans of the MEP blueprints and a digital model for a current project is shown, according to an exemplary embodiment. The configuration tool 600 can be configured to display the interface 1900 based on the input entered by the user via the interfaces 1200-1800. The interface 1900 may be displayed specifically when a user selects the detected tags tab 1902 in interfaces 1200-1800. Upon selecting the detected tags tab 1902, configuration tool 600 may be configured to present a portion of the MEP blueprints (e.g., a sheet or a segment of a sheet) in detail pane 1910 in a base layer. The portion of the MEP blueprints may include a segment of a sheet, shown as sheet 1912. Interface 900 is shown with floor plans tab 1940. In some embodiments, floor plans tab 1940 includes a list of sheets 1944. In some embodiments, configuration tool 600 may be configured to allow a user to group sheets 1944 into groups, shown as group 1942. Groups may represent, zones, rooms, floors, or other aspects of the building.

Sheet 1912 is shown to include a plurality of equipment tags 1914. In some embodiments, sheet 1912 contains multiple instances of one or more equipment tags 1914. Each equipment tag 1914 may be automatically identified by configuration tool 600 and/or machine learning agent 640 and added to the digital model. In some embodiments, the equipment tags 1914 which are added to the digital model are presented with a model object 1916 overlaid on the equipment tags 1914.

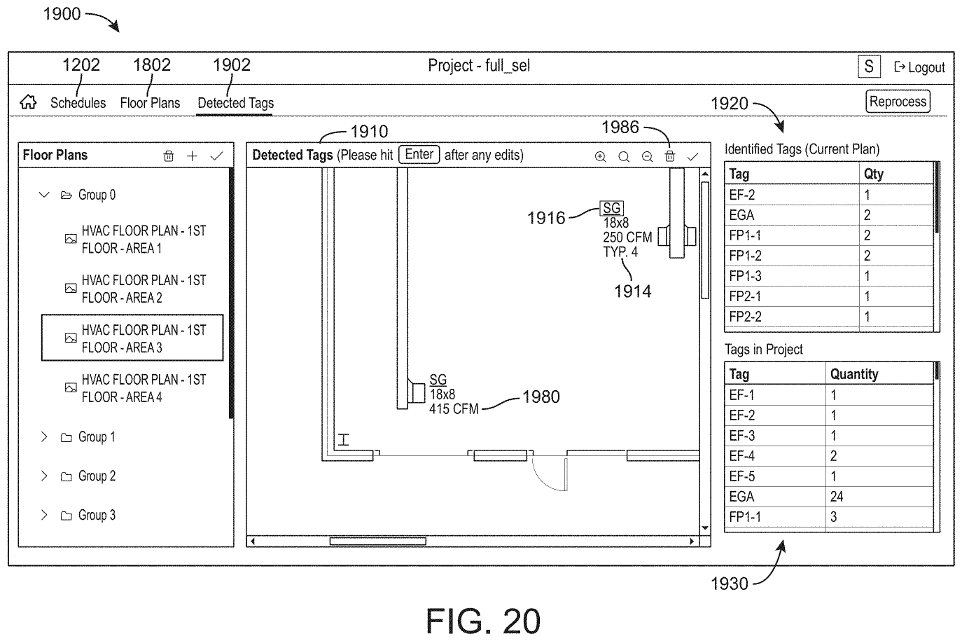

In some embodiments, the model object 1916 is presented in a model layer which overlays the base layer including the equipment tags 1914. Model object 1916 may indicate to a user that the instance of the equipment tag 1914 the model object 1916 is overlaid on top of has been identified and added to the digital model. In some embodiments, the model object 1916 also provide a user with a general view of equipment tags 1914 even if the text of the equipment tag 1914 is not rendered legibly. Model object 1916 may be seen more clearly below with reference to FIG. 20.

As shown in FIG. 20, user interface 1900 is shown with a user having zoomed in on a segment of sheet 1912. Equipment tags 1914 is shown with model object 1916 surrounding the text of the equipment tag 1914. Equipment tag 1980 is shown without a visual indication overlay (i.e., a model object), indicating that equipment tag 1980 is not included in the digital model. In some embodiments, a user may select model object 1916 and remove it from the digital model by selecting the delete element 1986. After removing the model object 1916, the equipment tag 1914 is no longer included in the digital model. In this manner, a user can review the sheets in the MEP blueprints and add, remove, or modify equipment tags to update the digital model as desired. As described above, only tags included in the digital model will be used when selecting building equipment components and determining a quote for the project.

Referring now to FIGS. 19-20, interface 1900 is shown with identified tags table 1920. In some embodiments, identified tags table 1920 is a sheet summary table listing the equipment tags 1914 identified in the sheet 1912 and the number of instances of each equipment tag 1914. For example, identified tags table 1920 is shown with a list of equipment tags 1914 including “FP1-1,” with a quantity of “1”, and “FP1-13” with a quantity of “2”. In some embodiments, only equipment tags 1914 with corresponding model objects 1916 are included in the identified tags table 1920. In some embodiments, identified tags table 1920 accounts for the inability of most digital displays to adequately render an entire sheet while the text is still legible to a human operator. By providing a sheet summary table (e.g., identified tags table 1920) in interface 1900, configuration tool 600 may allow a user to view the entirety of sheet 1912 while still providing the user with legible information regarding the equipment tags 1914 in sheet 1912 that could not be legible rendered in sheet 1912 itself. Relatedly, configuration tool 600 also allows a user to view only a small segment of the sheet 1912 and in the detail pane 1910 and yet still view an overview of equipment tags identified in the entire sheet 1912 in the identified tags table 1920.

Interface 900 is shown with project tags table 1930. In some embodiments, the project tags table 1930 is a project summary table listing the equipment tags 1914 identified throughout the entire project (i.e., in the entire MEP blueprints) with corresponding model objects 1916 and the number of identified instances for each equipment tag 1914 as represented by the number of model objects 1916. Similar to the identified tags table 1920, project tags table 1930 allows a user to view equipment tag information from multiple sheets of the MEP blueprints in as simplified and accessible manner without having to manually tabulate the number of equipment tags 1914.

In some embodiments, the identified tags table 1920 and the project tabs table 1930 are scrollable, and may present one or more rows of equipment tags. The equipment tags may be separated into rows and shown associated with the number of instances that equipment tag was found to have in the MEP blueprints.

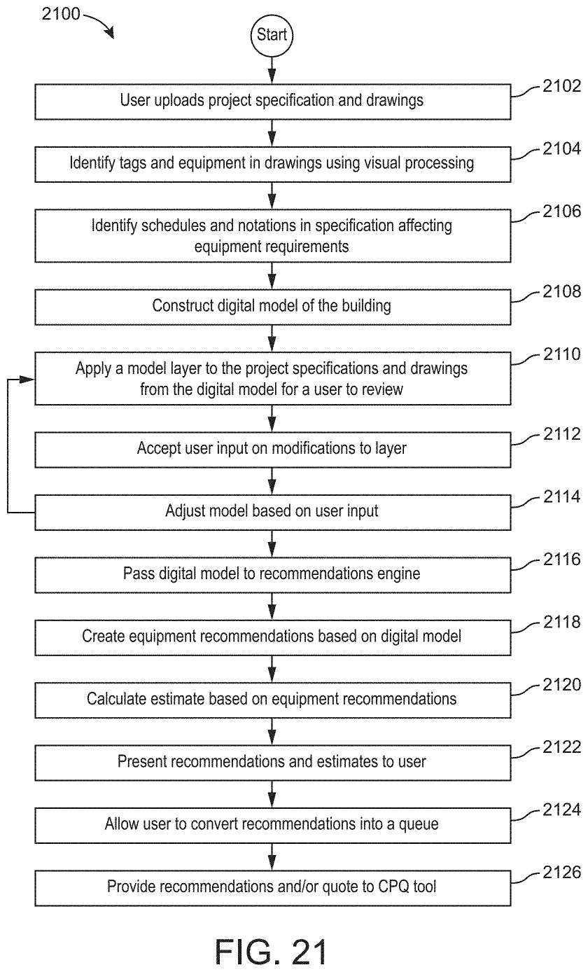

Referring now to FIG. 21, a flow diagram of a process 2100 for generating a digital model from project information and using that digital model to provide a recommendation is shown, according to an exemplary embodiment. Process 2100 may be performed by one or more components of the configuration tool 600 and/or other components shown in FIG. 6. Various examples of user interfaces that can be generated and presented to a user to facilitate some or all of the steps of process 700 are described in greater detail with reference to FIGS. 9-20.

Process 2100 is shown to include a user uploading project specification and drawings for the building (step 2102), identifying tags and equipment in the drawings using visual processing techniques (step 2104), identifying schedules and schedule notes in the project specification which affect equipment requirements (step 2106), constructing a digital model of the building including the building's HVAC/fire devices (step 2108), applying a layer to the drawings and specification documents for user review from the digital model (i.e., the model layer) (step 2110), accepting user input on modifications to the layer (step 2112), adjusting the digital model based on the user input (step 2114), where steps 2110-2114 can be repeated for as many modifications as desired by a user, passing the digital model to a recommendations engine (for example the project configuration 616) (step 2116), create equipment recommendations based on the digital model (step 2118), calculate a cost estimate based on the equipment recommendations (step 2120), present the recommendations and estimate to a user (step 2122), allow a user to convert the recommendations into a quote (step 2124) and provide the recommendations to a CPQ tool (step 2126). In some embodiments, steps 2102-2114 are the same as steps 702-714 in process 700.

At step 2102, a user uploads project specifications and drawings. In some embodiments, the user uploads the project specifications and drawings to the configuration tool 600. The project specifications and drawings can include a project name, a primary contractor, MEP blueprints of the building, and other information relevant to the project. In some embodiments, the project specifications and drawings are received via communications interface 630 from user device 650. The project specifications and drawings may MEP blueprints including one or more sheets of blueprints. Each sheet may include one or more schedules, schedule notes, floor plans, or detail views of a portion of the building. Each sheet may include multiple instances of various equipment tags indicating a type of building equipment and its location in the building.

At step 2104, process 2100 identifies tags and equipment in the drawings using visual processing. In some embodiments, the drawings are part of the MEP blueprints. The visual processing can include optical character recognition (OCR) and other text and image processing techniques to extract the relevant data from the project information that may be included in the digital model. Tags can be identified using a tag dictionary of potential tag identifiers. In some embodiments, the potential tag identifiers are alphanumeric strings indicating that a proceeding, or following (e.g., related) alphanumeric string is an equipment tag. The tags and equipment can be identified and associated in the digital model with a location based on the location they were identified in the drawings. In some embodiments, the equipment is also identified by tags.

At step 2106, process 2100 identifies schedules and schedule notes in the project specification affecting equipment requirements. In some embodiments, the project specification is found in the MEP blueprints. The schedules and/or schedule notes can include equipment requirements and design details indicating the engineer's performance and/or physical requirements for the building equipment.

At step 2108, process 2100 includes constructing a digital model of the building. The digital model may be a digital representation of the building based on the information in the project specification and drawings. The digital model can include information categorized by its location in the project specification such as the page number, x and y coordinate, etc., as well as by its location in the building itself such as by the floor, room, etc. The digital model can include model objects for each identified schedule, schedule note, floor plan, or tag/equipment that was identified in steps 2104 and 2106. In some embodiments, the digital model is generated using AI systems, such as machine learning agent 640.

At step 2110, process 2100 includes applying a model layer to the project specifications and drawings from the digital model for a user to review. In some embodiments, the project specifications and drawings are included in a base layer, and the model layer is overlaid on top of the base layer, allowing a user to see both the information source (i.e., the project specifications and drawings) as well the information that was extracted from the information and is now contained in the digital model. This can allow a user to review the digital model for accuracy and completeness. In some embodiments, GUI generator 620 may be configured to generate a user interface for display on user device 650 of at least a portion of the project specifications and drawings in a base layer and the digital model overlaid on top of the project specifications and drawings in a model layer.

At step 2112, process 2100 accepts user inputs on modifications to the model layer. The user inputs can be received through a user device, for example user device 650. The modifications can include editing a model object, deleting a model object, and/or adding a model object. For example, an identified tag contained in a model object may contain the alphanumeric string IDSA when the correct string as shown in the project specifications and documents is LDSA. A user can modify the tag model object to change the string. In some embodiments, the user can perform any of the modifications that are performed in step 710 of process 700.

At step 2114, process 2100 includes adjusting the model based on the user input. In some embodiments, a user input to a single model object can be propagated to related model objects. In some embodiments, a single user modification may propagate in a one-to-many manner when digital model is updated. For example, when a tag is modified, all other instances of the tag in the digital model can be automatically adjusted. In some embodiments, the digital model is updated by the configuration tool 600. Steps 2110-2114 can be repeated as many times as needed until a user is satisfied with the digital model.

At step 2116, the process 2100 passes the digital model to the recommendations engine.

In some embodiments, the digital model is passed by the communications interface 630. In some embodiments, the recommendations engine is the project configurator 616. For example, in configuration tool 600 the digital model may be received by the project configurator 616 from the digital model generator 614.

At step 2118, process 2100 creates equipment recommendations based on the digital model. In some embodiments, when making the equipment recommendations, performance metrics for the various identified types of building equipment in the digital model are first calculated, and the performance metrics are used to determine the equipment recommendations. The equipment recommendations can also be based on the schedules and/or schedule notes which can include equipment requirements and design details indicating the engineer's performance and/or physical requirements for the building equipment. Using the information in schedule, and/or the number of pieces of equipment needed as indicated by the number of instances of an associated equipment tag identified in the project information, performance metrics and/or equipment recommendations can be calculated for the building equipment type. In some embodiments, performance metrics calculated first before the equipment recommendations because the performance metrics are a better indication to use for selecting specific building equipment components than general design specifications found in a schedule. In some embodiments, an artificial intelligence system, such as machine learning agent 640, selects the specific building equipment from a data base of building equipment, such as building equipment database 622. In some embodiments, a user may select specific preferred equipment, deselect unwanted equipment, and otherwise modify the list of recommended equipment.

At step 2120, the process 2100 calculates an estimate based on the equipment recommendations. The estimate can be an estimate for the total cost of the project, but in some embodiments the estimate can also be broken down by equipment, floor, equipment type, etc. In some embodiments, the estimate is provided to a user for view. The user may review and modify the estimate. In some embodiments, the estimate is generated by the project estimator 618.

At step 2122, the process 2100 includes presenting the recommendations and estimate to a user. In some embodiments, the recommendations and estimate are presented to a user on a user interface of the user device 650. The estimate and recommendations can also be modified by the user, for example, selected a different piece of building equipment then was recommended.

At step 2124, the process 2100 allows a user to convert the recommendations and estimate into a quote. In some embodiments, the quote can be provided directly to a requesting party such as a customer. In other embodiments, the quote and/or recommendation can be provided to a configuration, price, or quote (CPQ) tool, as in step 2126. The recommendations and/or quote can be provided via the communications interface 630.

### Configuration of Exemplary Embodiments

The construction and arrangement of the systems and methods as shown in the various exemplary embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements can be reversed or otherwise varied and the nature or number of discrete elements or positions can be altered or varied. Accordingly, all such modifications are intended to be included within the scope of the present disclosure. The order or sequence of any process or method steps can be varied or re-sequenced according to alternative embodiments. Other substitutions, modifications, changes, and omissions can be made in the design, operating conditions and arrangement of the exemplary embodiments without departing from the scope of the present disclosure.

The present disclosure contemplates methods, systems and program products on any machine-readable media for accomplishing various operations. The embodiments of the present disclosure can be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures show a specific order of method steps, the order of the steps may differ from what is depicted. Also two or more steps can be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

What is claimed is:

1. A system for configuring a digital model of a building comprising:
one or more memory devices having instructions stored thereon that, when executed by one or more processors, cause the one or more processors to perform operations comprising:
receiving project information including project specifications and drawings for the building;
generating a digital model of the building based on the project information, wherein generating the digital model comprises:
extracting, from the project information, one or more schedules, schedule notes, floor plans, or identified tags; and
associating each of the one or more schedules, schedule notes, floor plans, or identified tags with a corresponding location in the project information;
presenting, on a user interface, a portion of the project information in a base layer; and
presenting, on the user interface, a model layer overlaying the base layer, the model layer comprising one or more model objects representing each of the one or more schedules, schedule notes, floor plans, or identified tags in the digital model, wherein the model objects are rendered in the model layer at a position on the user interface according to the corresponding location of the one or more schedules, schedule notes, floor plans, or identified tags in the base layer.

2. The system of claim 1, further comprising:
updating the digital model based on a user input, wherein updating comprises:
receiving a user input modifying at least one of the one or more schedules, schedule notes, floor plans, or identified tags;
extracting, from the drawings, one or more updated identified tags; and
associating the one or more updated identified tags with a corresponding location in the drawings; and
presenting, in the model layer on the user interface, one or more model objects representing each of the one or more updated identified tags.

3. The system of claim 1, wherein the one or more schedules, schedules notes, floor plans, or identified tags are extracted using an artificial intelligence (AI) agent.

4. The system of claim 1, wherein generating the digital model further comprises:
obtaining a tag dictionary including a list of potential tag identifiers; and
extracting one or more identified tags using the tag dictionary.

5. The system of claim 1, wherein generating the digital model further comprises:
identifying a floor in the building based on the project information;
generating a corresponding floor in the digital model; and
associating in the digital model each of the one or more schedules, schedule notes, floor plans, or identified tags with a corresponding location on the floor.

6. The system of claim 1, wherein the portion is of a first sheet of a plurality of sheets in the drawings, the system further comprising presenting, on the user interface, a sheet summary table listing the one or more identified tags associated with the first sheet and a number of instances of each identified tag located on the first sheet.

7. The system of claim 1, further comprising communicating the digital model to a machine learning agent configured to use the digital model to determine at least one of the plurality of building equipment components capable of being used in the building.

8. The system of claim 1, further comprising:
associating a type of building equipment with at least one of the one or more schedules;
associating at least one schedule note with the at least one of the one or more schedules;
calculating a performance metric for the type of building equipment based on the one or more associated schedules and the at least one schedule note; and
selecting a building equipment component from a plurality of building equipment components based on the performance metric.

9. The system of claim 1, further comprising:
identifying, for each of the one or more schedules extracted from the project information, essential schedule information;
reducing each of the one or more schedules in the digital model to the identified essential schedule information; and
updating the digital model with the one or more reduced schedules.

10. The system of claim 1, further comprising:
selecting, using the digital model, building equipment components for each for each of the one or more identified tags; and
generating a quote for the selected building equipment components.

11. A method for configuring a digital model of a building comprising:
receiving project information including project specifications and drawings for the building;
generating a digital model of the building based on the project information, wherein generating the digital model comprises:
extracting, from the project information, one or more schedules, schedule notes, floor plans, or identified tags; and
associating each of the one or more schedules, schedule notes, floor plans, or identified tags with a corresponding location in the project information; and
presenting, on a user interface, a portion of the project information in a base layer; and
presenting, on the user interface, a model layer overlaying the base layer, the model layer comprising one or more model objects representing each of the one or more schedules, schedule notes, floor plans, or identified tags in the digital model, wherein the model objects are rendered at a position on the user interface in the model layer according to the corresponding location of the one or more schedules, schedule notes, floor plans, or identified tags in the base layer.

12. The method of claim 11, further comprising:
updating the digital model based on a user input, wherein updating comprises:
receiving a user input modifying at least one of the one or more schedules, schedule notes, floor plans, or identified tags;
extracting, from the project information, one or more updated identified tags; and
associating the one or more updated identified tags with a corresponding location in the project information; and
presenting, in the model layer on the user interface, one or more model objects representing each of the one or more updated identified tags.

13. The method of claim 11, wherein the one or more schedules, schedule notes, floor plans, or identified tags are extracted using an artificial intelligence (AI) agent.

14. The method of claim 11, wherein generating the digital model further comprises:
obtaining a tag dictionary including a list of potential tag identifiers; and
extracting the one or more identified tags using the tag dictionary.

15. The method of claim 11, wherein generating the digital model further comprises:
identifying a floor in the building based on the project information;
generating a corresponding floor in the digital model; and
associating in the digital model each of the one or more schedules, schedule notes, floor plans, or identified tags with a corresponding location on the floor.

16. The method of claim 11, wherein the portion is of a first sheet of a plurality of sheets in the drawings, the system further comprising presenting, on the user interface, a sheet summary table listing the one or more identified tags associated with the first sheet and a number of instances of each identified tag located on the first sheet.

17. The method of claim 11, further comprising communicating the digital model to a machine learning agent configured to use the digital model to determine at least one of the plurality of building equipment components capable of being used in the building.

18. The method of claim 11, further comprising:
associating a type of building equipment with at least one of the one or more schedules;
associating at least one schedule note with the at least one of the one or more schedules;
calculating a performance metric for the type of building equipment based on the one or more associated schedules and the at least one schedule note; and
selecting a building equipment component from a plurality of building equipment components based on the performance metric.

19. The method of claim 11, further comprising:
identifying, for each of the one or more schedules extracted from the project information, essential schedule information;
reducing each of the one or more schedules in the digital model to the identified essential schedule information; and
updating the digital model with the one or more reduced schedules.

20. The method of claim 11, further comprising:
selecting, using the digital model, building equipment components for each for each of the one or more identified tags; and
generating a quote for the selected building equipment components.
